(19) United States
(12) Patent Application Publication
(10) Pub. No.: US 2026/0006947 A1
(43) Pub. Date: Jan. 1, 2026

(54) LIGHT EMITTING ELEMENT, AND DISPLAY DEVICE AND ELECTRONIC DEVICE INCLUDING THE SAME

(71) Applicant: Samsung Display Co., LTD., Yongin-si (KR)

(72) Inventors: Jin Wan KIM, Yongin-si (KR); Dae Hong MIN, Yongin-si (KR); Byung Ju LEE, Yongin-si (KR)

(73) Assignee: Samsung Display Co., LTD., Yongin-si (KR)

(21) Appl. No.: 19/058,295

(22) Filed: Feb. 20, 2025

(30) Foreign Application Priority Data
Jun. 28, 2024 (KR) 10-2024-0085555

(51) Int. Cl. H10H 20/815; H10H 20/812; H10H 20/825; H10H 29/49

(52) U.S. Cl. CPC H10H 20/815; H10H 20/812; H10H 20/825; H10H 29/49

(57) ABSTRACT

A light emitting element according to an embodiment includes a first semiconductor layer, a stress relief layer disposed on the first semiconductor layer, a light emitting layer disposed on the stress relief layer, and a second semiconductor layer disposed on the light emitting layer, and the light emitting element further includes an absorption layer above or below the light emitting layer and absorbing light of a wavelength band corresponding to a bandgap energy of the stress relief layer.

### CROSS-REFERENCE TO RELATED APPLICATION(S)

This application claims priority to and benefits of Korean Patent Application No. 10-2024-0085555 filed on Jun. 28, 2024 under 35 U.S.C. 119, in the Korean Intellectual Property Office, the entire contents of which are incorporated herein by reference.

### BACKGROUND

### 1. Technical Field

Embodiments relate to a light emitting element, and a display device and electronic device including the same.

### 2. Description of the Related Art

Light emitting elements are widely used as light sources of various electronic devices including display devices. For example, the light emitting elements are used as light sources of various electronic devices including virtual reality (VR) devices and augmented reality (AR) devices as well as portable electronic devices and televisions.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a light emitting element with improved color purity, and a display device and an electronic device including the same.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, there is provided a light emitting element that may include a first semiconductor layer; a stress relief layer disposed on the first semiconductor layer; a light emitting layer disposed on the stress relief layer; and a second semiconductor layer disposed on the light emitting layer, the light emitting element further including an absorption layer disposed above or below the light emitting layer and absorbing light of a wavelength band corresponding to a bandgap energy of the stress relief layer.

In an embodiment, the stress relief layer, the light emitting layer and the absorption layer may contain a nitride-based semiconductor material containing indium.

In an embodiment, the stress relief layer may include an indium-containing layer containing a nitride-based semiconductor material containing indium, and the light emitting layer may include a quantum well layer containing a nitride-based semiconductor material containing indium at a composition higher than an indium composition of the indium-containing layer.

In an embodiment, an indium composition of the absorption layer may be higher than the indium composition of the indium-containing layer and lower than an indium composition of the quantum well layer.

In an embodiment, an indium composition of the quantum well layer may be about 25% or more.

In an embodiment, a bandgap energy of the absorption layer may have a value between a bandgap energy of the indium-containing layer and a bandgap energy of the quantum well layer.

In an embodiment, the stress relief layer may be formed as multiple layers including a plurality of indium-containing layers and a plurality of intermediate layers alternately stacked with the plurality of indium-containing layers, and the absorption layer may be formed as a single layer containing indium.

In an embodiment, a thickness of the absorption layer may be in a range of about 10 nm to about 100 nm.

In an embodiment, the stress relief layer may include at least one of, a first stress relief layer disposed on the first semiconductor layer and containing indium at a composition of less than about 10%, and a second stress relief layer disposed on the first semiconductor layer or the first stress relief layer and containing indium at a composition of about 10% or more.

In an embodiment, the absorption layer may include at least one of, a first absorption layer disposed between the first semiconductor layer and the light emitting layer, and a second absorption layer disposed between the light emitting layer and the second semiconductor layer.

In an embodiment, the first absorption layer may be disposed on at least one of between the stress relief layer and the light emitting layer, between the first semiconductor layer and the stress relief layer, and between a first stress relief layer and a second stress relief layer included in the stress relief layer.

In an embodiment, the light emitting layer may include quantum well layers and barrier layers alternately stacked with each other, and the second absorption layer may be disposed between a last quantum well layer and a last barrier layer of the light emitting layer, or on top of the last barrier layer.

In an embodiment, the absorption layer may contain a first conductivity type dopant or a second conductivity type dopant.

In an embodiment, a doping concentration of the first conductivity type dopant or the second conductivity type dopant may be about 10¹⁸/cm³ or more.

In an embodiment, a wavelength of light emitted from the light emitting layer may be about 600 nm or more.

According to an aspect of the disclosure, there is provided a display device that may include a first electrode; a second electrode; and a light emitting element electrically connected between the first electrode and the second electrode, the light emitting element including a first semiconductor layer and a second semiconductor layer overlapping each other, a light emitting layer disposed between the first semiconductor layer and the second semiconductor layer, a stress relief layer disposed between the first semiconductor layer and the light emitting layer, and an absorption layer disposed on at least one of between the first semiconductor layer and the light emitting layer or between the second semiconductor layer and the light emitting layer, and absorbing light of a wavelength band corresponding to a band gap energy of the stress relief layer.

In an embodiment, the light emitting layer, the stress relief layer, and the absorption layer may contain a nitride-based semiconductor material containing indium, and an indium composition of the absorption layer may be higher than an indium composition of an indium-containing layer included in the stress relief layer, and lower than an indium composition of a quantum well layer included in the light emitting layer.

In an embodiment, a bandgap energy of the absorption layer may have a value between a bandgap energy of the indium-containing layer and a bandgap energy of the quantum well layer.

In an embodiment, the stress relief layer may be formed as multiple layers including a plurality of indium-containing layers and a plurality of intermediate layers alternately stacked with the plurality of indium-containing layers, and the absorption layer may be formed as a single layer containing indium and having a thickness in a range of about 10 nm to about 100 nm.

In an embodiment, the absorption layer may contain a first conductivity type dopant or a second conductivity type dopant.

According to an aspect of the disclosure, there is provided an electronic device that may include a display device, the display device including a first electrode, a second electrode, and a light emitting element electrically connected between the first electrode and the second electrode, wherein the light emitting element may include a first semiconductor layer and a second semiconductor layer overlapping each other, a light emitting layer disposed between the first semiconductor layer and the second semiconductor layer, a stress relief layer disposed between the first semiconductor layer and the light emitting layer, and an absorption layer disposed on at least one of between the first semiconductor layer and the light emitting layer or between the second semiconductor layer and the light emitting layer, and absorbing light of a wavelength band corresponding to a band gap energy of the stress relief layer. In an embodiment, the light emitting layer, the stress relief layer, and the absorption layer may contain a nitride-based semiconductor material containing indium, and an indium composition of the absorption layer is higher than an indium composition of an indium-containing layer comprised in the stress relief layer, and lower than an indium composition of a quantum well layer comprised in the light emitting layer.

The light emitting element according to embodiments may include a stress relief layer disposed between a first semiconductor layer and a light emitting layer, and an absorption layer disposed above or below the light emitting layer. The absorption layer may transmit light of a first color generated in the light emitting layer, and absorb light of other colors that may be generated in the stress relief layer and the like within the spirit and the scope of the disclosure. According to embodiments, a high-quality light emitting element with improved color purity, and a display device and an electronic device including the same may be provided.

However, effects according to the embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view showing a light emitting element according to an embodiment;

FIG. 2 is a schematic cross-sectional view showing a light emitting element according to an embodiment;

FIG. 3 is a schematic cross-sectional view showing a light emitting layer according to an embodiment;

FIG. 4 is a schematic cross-sectional view showing a first stress relief layer according to an embodiment;

FIG. 5 is a schematic cross-sectional view showing a second stress relief layer according to an embodiment;

FIGS. 6 to 18 are schematic cross-sectional views showing light emitting elements according to embodiments;

FIG. 19 is a schematic perspective view illustrating a display device according to an embodiment;

FIG. 20 is a schematic cross-sectional view showing a display device according to an embodiment;

FIG. 21 is a diagram illustrating a smart watch including a display device according to an embodiment;

FIGS. 22 and 23 are views illustrating a head mounted display including a display device according to an embodiment;

FIG. 24 is a view illustrating a head mounted display including a display device according to an embodiment;

FIG. 25 is a diagram illustrating a dashboard of an automobile and a center fascia including display devices according to an embodiment; and

FIG. 26 is a diagram illustrating a transparent display device including a display device according to an embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when an element or a layer is referred to as being “on” element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Features of each of various embodiments of the disclosure may be partially or entirely combined with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

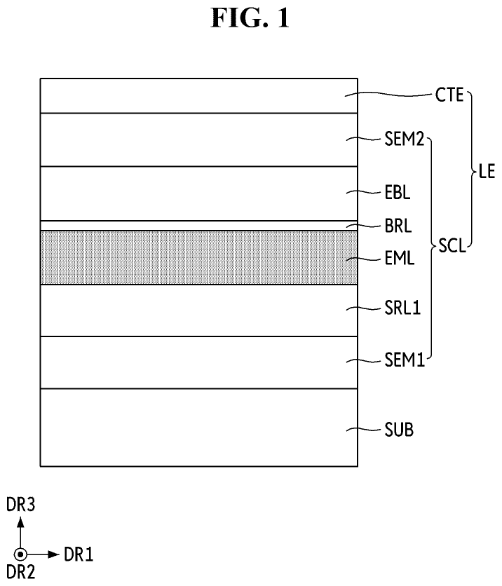

FIG. 1 is a schematic cross-sectional view showing a light emitting element according to an embodiment.

Referring to FIG. 1, the light emitting element LE may be disposed on a substrate SUB. In an embodiment, the light emitting element LE may be manufactured on the substrate SUB and separated from the substrate SUB.

FIG. 1 shows a first direction DR1, a second direction DR2, and a third direction DR3 that are perpendicular to each other. For example, the first direction DR1 and the second direction DR2 may be perpendicular to each other and define a plane parallel to the bottom surface (for example, lower surface or upper surface) of the light emitting element LE or the substrate SUB. The third direction DR3 may be perpendicular to the first direction DR1 and the second direction DR2. For example, the third direction DR3 may be a direction perpendicular to the main surface of the substrate SUB and may be a height direction or a thickness direction of the substrate SUB or the light emitting element LE.

The substrate SUB (also referred to as “growth substrate” or “manufacturing substrate”) may be a semiconductor substrate for forming the light emitting element LE. The substrate SUB may be a wafer or a manufacturing substrate suitable for epitaxial growth. For example, semiconductor layers SCL of the light emitting element LE may be formed on the substrate SUB by epitaxial growth.

In an embodiment, the substrate SUB may be a semiconductor substrate including silicon (Si), sapphire, GaAs, SiC, GaN, ZnO, or another material. In case that epitaxial growth for manufacturing the light emitting element LE may be performed smoothly, the type or material of the substrate SUB is not particularly limited.

In an embodiment, the substrate SUB may be used as a substrate for epitaxial growth for manufacturing the light emitting element LE and may be finally separated from the light emitting element LE. For example, after sequentially forming (for example, growing or re-growing) the semiconductor layers SCL to form the light emitting element LE on the substrate SUB, light emitting elements LE having a size (for example, an area smaller than the area of the substrate SUB) smaller than the size of the substrate SUB may be formed by an etching process, dicing, or the like within the spirit and the scope of the disclosure. For example, after forming the light emitting elements LE on the substrate SUB at the same time, the light emitting elements LE may be separated from the substrate SUB. By way of example, in a state in which the semiconductor layers SCL are disposed on the substrate SUB and bonded to a backplane substrate (or a backplane substrate including cell areas for simultaneously manufacturing display devices) for manufacturing a display device and the like, the substrate SUB may be separated from the semiconductor layers SCL and the semiconductor layers SCL may be etched to form the light emitting elements LE on the backplane substrate.

The light emitting element LE may have various forms depending on embodiments. In an embodiment, the light emitting element LE may include a side surface that is substantially perpendicular to the substrate SUB. For example, the light emitting element LE may have a cross-sectional shape such as a rectangular shape or a square shape. However, the shape of the light emitting element LE is not limited thereto. For example, the light emitting element LE may include a side surface inclined at a taper angle with respect to the substrate SUB. For example, the light emitting element LE may have a cross-sectional shape such as a trapezoid or an inverted trapezoid. The light emitting element LE may have various planar shapes depending on embodiments. For example, the light emitting element LE may have a rectangular shape, a square shape, a hexagonal shape, a circular shape, an elliptical shape, or another planar shape when viewed on a plane defined by the first direction DR1 and the second direction DR2. In plan view, the light emitting element LE may have a size substantially the same as or similar to the substrate SUB, or may have a size smaller than the substrate SUB.

In an embodiment, the light emitting element LE may be an inorganic light emitting element made of an inorganic material. For example, the light emitting element LE may be an inorganic light emitting diode made of a nitride-based semiconductor material (for example, GaN, AlGaN, GaAlN, InGaN, InAlGaN, AlN, InN, or another nitride-based semiconductor material), or another inorganic material. The light emitting element LE may emit light of a given color. For example, the light emitting element LE may emit red light, green light, blue light, or light of another color. In an embodiment, a light emitting layer EML of the light emitting element LE may contain indium, and may emit light of a color and/or wavelength band corresponding to the indium composition (or content) of the light emitting layer EML.

In an embodiment, the light emitting element LE may be a micro light emitting diode (micro LED) having a small size in the micrometer (μm) range. For example, the light emitting element LE may be a micro LED having a length (for example, horizontal length) in the first direction DR1, a length (for example, vertical length) in the second direction DR2, and a length (for example, thickness or height) in the third direction DR3, which are several to hundreds of micrometers, respectively. Each of the length of the light emitting element LE in the first direction DR1, the length in the second direction DR2, and the length in the third direction DR3 may be 100 μm or less, but is not limited thereto.

The light emitting element LE may include the semiconductor layers SCL (also referred to as “semiconductor thin film layers”, “epitaxial layers”, or “light emitting stacks”) disposed or stacked on the substrate SUB. In an embodiment, the semiconductor layers SCL of the light emitting element LE may include a first semiconductor layer SEM1, a first stress relief layer SRL1 (for example, a strain relaxation layer), the light emitting layer EML (for example, an active layer of the light emitting element LE), an electron blocking layer EBL, and a second semiconductor layer SEM2, which are sequentially disposed or stacked on the substrate SUB.

In an embodiment, the light emitting layer EML may include at least one quantum well layer and at least one barrier layer BRL, and the barrier layer BRL may be disposed at the uppermost portion of the light emitting layer EML. In FIG. 1, the barrier layer BRL (for example, the last barrier layer BRL of the light emitting layer EML) disposed at the uppermost portion of the light emitting layer EML is shown separately from the light emitting layer EML to illustrate the position of the last barrier layer BRL. The last barrier layer BRL may be considered as an element included in the light emitting layer EML, or may be considered as an element separate from the light emitting layer EML and disposed directly on the light emitting layer EML (for example, on the last quantum well layer of the light emitting layer EML).

In an embodiment, the light emitting element LE may further include at least one contact electrode CTE. As an example, the light emitting element LE may further include the contact electrode CTE disposed on the second semiconductor layer SEM2.

In an embodiment, the light emitting element LE may further include a protective layer that surrounds the outer peripheral surface (for example, the side surface) of the semiconductor layers SCL. The protective layer may or may not surround the contact electrode CTE. The protective layer may expose at least a portion (for example, the top surface) of the contact electrode CTE.

The first semiconductor layer SEM1 may be disposed on the substrate SUB. The first semiconductor layer SEM1 may be a semiconductor layer doped with a first conductivity type. For example, the first semiconductor layer SEM1 may include a semiconductor material including a first conductivity type dopant.

In an embodiment, the first semiconductor layer SEM1 may include a nitride-based semiconductor material and a first conductivity type dopant doped into the nitride-based semiconductor material. For example, the first semiconductor layer SEM1 may be an n-type semiconductor layer (for example, n-GaN) doped with an n-type dopant such as Si, Ge, and Sn, but is not limited thereto.

The first stress relief layer SRL1 may be disposed on the first semiconductor layer SEM1. The first stress relief layer SRL1 may contain indium. For example, the first stress relief layer SRL1 may contain a nitride-based semiconductor material (for example, InGaN or AlInGaN) containing indium.

In embodiments, the indium composition of the first stress relief layer SRL1 may be lower than the indium composition of the light emitting layer EML. For example, the indium composition of the first stress relief layer SRL1 may be less than about 30% of the indium composition of the quantum well layer included in the light emitting layer EML. In an embodiment, the indium composition of the first stress relief layer SRL1 may be less than about 10% (for example, in a range of about 2% to about 5%), but is not limited thereto. By containing indium at a low composition, the first stress relief layer SRL1 may be smoothly formed (for example, grown) on the first semiconductor layer SEM1. In describing embodiments, the term “indium composition” refers to the proportion or concentration of indium contained in a corresponding layer or material, and it may also encompass the meaning of “indium content.” For example, in describing embodiments, the term “composition” may also encompass the meaning of “content.”

The lattice constant (for example, average lattice constant) of the first stress relief layer SRL1 may be greater than or equal to the lattice constant of the first semiconductor layer SEM1, and may be less than or equal to the lattice constant of the light emitting layer EML. For example, the lattice constant of the first stress relief layer SRL1 may have a value between the lattice constant of the first semiconductor layer SEM1 and the lattice constant of the light emitting layer EML.

By disposing the first stress relief layer SRL1 between the first semiconductor layer SEM1 and the light emitting layer EML, a lattice mismatch between the first semiconductor layer SEM1 and the light emitting layer EML may be mitigated, and the light emitting layer EML may be more smoothly formed. For example, by first growing the first stress relief layer SRL1 with an intermediate lattice size between the first semiconductor layer SEM1 and the light emitting layer EML and growing the light emitting layer EML, indium may be smoothly injected into the light emitting layer EML.

For example, the stress (for example, in-plain strain) due to the difference in lattice constants of the first semiconductor layer SEM1 and the light emitting layer EML may be mitigated by the first stress relief layer SRL1. Accordingly, in the step of forming the light emitting layer EML on the first stress relief layer SRL1, indium may be smoothly injected into the light emitting layer EML according to the targeted indium composition, and the high-quality light emitting layer EML with reduced defects may be formed. In addition, defects that may occur on the surface of the first semiconductor layer SEM1 (for example, the interface between the first semiconductor layer SEM1 and the first stress relief layer SRL1) may be reduced. Accordingly, the high-quality and/or high-efficiency light emitting element LE may be manufactured.

In an embodiment, the first stress relief layer SRL1 may be formed to have a thickness less than or equal to the thickness of the first semiconductor layer SEM1. In an embodiment, the first stress relief layer SRL1 may be a superlattice layer including indium-containing layers containing indium at a low composition and intermediate layers alternately stacked with the indium-containing layers.

The first stress relief layer SRL1 may be doped or undoped. In an embodiment, the first stress relief layer SRL1 may be doped with a first conductivity type dopant, thereby improving the conductivity of the first stress relief layer SRL1. In an embodiment, the doping concentration of the first stress relief layer SRL1 may be less than or equal to the doping concentration of the first semiconductor layer SEM1. For example, the doping concentration of the first semiconductor layer SEM1 may be about 3*10¹⁸/cm³ or more, and the doping concentration of the first stress relief layer SRL1 may be lower than about 3*10¹⁸/cm³. Accordingly, although the first stress relief layer SRL1 is formed at a growth temperature lower than or equal to the growth temperature of the first semiconductor layer SEM1, the high-quality first stress relief layer SRL1 with reduced defects may be formed, and defects that may occur at the interface between the first stress relief layer SRL1 and the first semiconductor layer SEM1 may be reduced.

The light emitting layer EML may be disposed on the first stress relief layer SRL1. For example, the light emitting layer EML may be disposed between the first stress relief layer SRL1 and the second semiconductor layer SEM2. The light emitting layer EML may emit light by recombination of electron-hole pairs generated in response to an electrical signal applied through the first semiconductor layer SEM1, the second semiconductor layer SEM2 and the like within the spirit and the scope of the disclosure.

The light emitting layer EML may include a nitride-based semiconductor material or another semiconductor material, and may have a single or multiple quantum well structure. For example, the light emitting layer EML may include at least one quantum well layer including a nitride-based semiconductor material (for example, InGaN or AlInGaN) containing indium. In embodiments, the quantum well layer may include a nitride-based semiconductor material including indium in a composition greater than or equal to the indium composition of the first stress relief layer SRL1 (or the indium-containing layer of the first stress relief layer SRL1). In an embodiment, the light emitting layer EML may have a multiple quantum well structure including quantum well layers including InGaN and barrier layers including GaN, AlGaN, or GaAlN, but is not limited thereto.

In an embodiment, the light emitting layer EML may emit light in a visible light wavelength band, for example, light in a wavelength band of in a range of about 400 nm to about 900 nm. For example, the light emitting layer EML may emit blue light having a peak wavelength within a range of about 440 nm to about 480 nm, green light having a peak wavelength within a range of about 510 nm to about 550 nm, or red light having a peak wavelength within a range of about 610 nm to about 750 nm (for example, about 610 nm to about 650 nm). The light emitting layer EML may emit light whose color or wavelength band is different from the color or the wavelength band described above.

In an embodiment, the color of light emitted from the light emitting layer EML may be adjusted or changed by adjusting the composition of indium contained in the light emitting layer EML. For example, by controlling the composition of indium included in the light emitting layer EML to a range of about 20% to about 30%, the emission wavelength of the light emitting layer EML may be controlled such that the light emitting layer EML emits green light. By way of example, by controlling the composition of indium included in the light emitting layer EML to a range of about 30% to about 40%, the emission wavelength of the light emitting layer EML may be controlled such that the light emitting layer EML emits red light.

In an embodiment, the indium composition (for example, the indium composition of the quantum well layer) of the light emitting layer EML may be about 25% or more, and the emission wavelength (for example, emission peak wavelength) of the light emitting layer EML may be in a range of about 500 nm to about 750 nm. Accordingly, the light emitting layer EML may emit light (for example, green light or red light) of a long wavelength that is equal to or longer than the green wavelength band. In an embodiment, the indium composition of the light emitting layer EML may be about 30% or more (for example, about 35%), and red light having a long wavelength of about 600 nm or more may be emitted from the light emitting layer EML. Even if the light emitting layer EML contains indium at a composition of about 30% or more, the light emitting layer EML may be appropriately or readily formed due to the lattice matching effect by the first stress relief layer SRL1 or the like within the spirit and the scope of the disclosure.

In an embodiment, the indium composition of the light emitting layer EML (or the quantum well layer included in the light emitting layer EML) may be higher the indium composition of the first stress relief layer SRL1 (or a first layer included in the first stress relief layer SRL1). Accordingly, indium fluctuation in the light emitting layer EML may be higher than indium fluctuation in the first stress relief layer SRL1. For example, the indium fluctuation in the light emitting layer EML may be at least about 10% higher than the indium fluctuation in the first stress relief layer SRL1.

The electron blocking layer EBL may be disposed on the light emitting layer EML. The electron blocking layer EBL may prevent electrons injected from the light emitting layer EML from migrating to the second semiconductor layer SEM2, thereby increasing the likelihood that electrons and holes recombine in the light emitting layer EML. In an embodiment, the electron blocking layer EBL may contain aluminum-doped GaN, for example, AlGaN, but is not limited thereto.

The second semiconductor layer SEM2 may be disposed on the electron blocking layer EBL (or the light emitting layer EML). The second semiconductor layer SEM2 may be a semiconductor layer doped with a dopant of a second conductivity type. For example, the second semiconductor layer SEM2 may include a semiconductor material including a second conductivity type dopant.

In an embodiment, the second semiconductor layer SEM2 may include a nitride-based semiconductor material and a second conductivity type dopant doped into the nitride-based semiconductor material. For example, the second semiconductor layer SEM2 may be a p-type semiconductor layer (for example, p-GaN) doped with a p-type dopant such as Mg, Zn, Ca, Se, and Ba, but is not limited thereto.

The contact electrode CTE may be disposed on the semiconductor layers SCL of the light emitting element LE. For example, the contact electrode CTE may be disposed on the second semiconductor layer SEM2. The contact electrode CTE may be provided to the light emitting element LE to protect the second semiconductor layer SEM2 and smoothly connect the second semiconductor layer SEM2 to at least one electrode, circuit element, or wire, or the like within the spirit and the scope of the disclosure.

In an embodiment, the contact electrode CTE may be entirely disposed on the second semiconductor layer SEM2. As an example, the contact electrode CTE may have a size corresponding to the second semiconductor layer SEM2 and may entirely cover the upper surface of the second semiconductor layer SEM2. Accordingly, the second semiconductor layer SEM2 may be appropriately or stably protected. However, the embodiments are not limited thereto. For example, the contact electrode CTE may be formed to cover only a portion of the second semiconductor layer SEM2 and expose another portion of the second semiconductor layer SEM2.

The contact electrode CTE may include metal, metal oxide, or other conductive materials. For example, metal such as chromium (Cr), titanium (Ti), aluminum (Al), gold (Au), nickel (Ni), or copper (Cu), an oxide or an alloy thereof, and a transparent conductive material such as indium tin oxide (ITO), indium zinc oxide (IZO), indium tin zinc oxide (ITZO), zinc oxide (ZnO), or indium oxide (In₂O₃) may be used alone or mixed to form the contact electrode CTE, but the disclosure is limited thereto. In case that the contact electrode CTE contains a transparent conductive material and is substantially transparent, light generated in the light emitting layer EML may pass through the contact electrode CTE and be emitted to the outside of the light emitting element LE.

In an embodiment, the light emitting element LE may further include an additional electrode. In one example, the light emitting element LE may further include at least one of a first electrode (for example, an anode electrode) disposed on the contact electrode CTE (or the second semiconductor layer SEM2) and electrically connected to the contact electrode CTE (or the second semiconductor layer SEM2), or a second electrode (for example, a cathode electrode) disposed on the first semiconductor layer SEM1 and electrically connected to the first semiconductor layer SEM1. In an embodiment, in case that the light emitting element LE further may include the second electrode, other upper semiconductor layers, the contact electrode CTE, and/or the like may be disposed only above a portion of the first semiconductor layer SEM1, while the second electrode may be disposed on another exposed portion of the first semiconductor layer SEM1.

The first electrode of the light emitting element LE may be a first connection electrode (or first bonding electrode) to smoothly connect the contact electrode CTE (or the second semiconductor layer SEM2) to another circuit element, electrode, or wire, or the like within the spirit and the scope of the disclosure. The second electrode of the light emitting element LE may be a second connection electrode (or second bonding electrode) to smoothly connect the first semiconductor layer SEM1 to another circuit element, electrode, wire, or the like within the spirit and the scope of the disclosure. Each of the first and second electrodes of the light emitting element LE may contain a metal, a metal oxide, or another conductive material. For example, each of the first and second electrodes of the light emitting element LE may include any one of molybdenum (Mo), aluminum (Al), chromium (Cr), gold (Au), titanium (Ti), nickel (Ni), neodymium (Nd), and copper (Cu), but is not limited thereto.

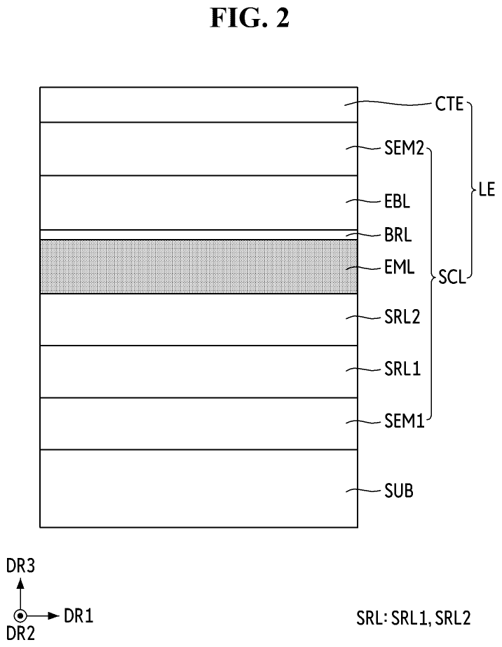

FIG. 2 is a schematic cross-sectional view showing a light emitting element according to an embodiment. Compared to FIG. 1, FIG. 2 shows the light emitting element LE further including a second stress relief layer SRL2.

Referring to FIGS. 1 and 2, the light emitting element LE may further include the second stress relief layer SRL2 (for example, a strain relaxation layer) disposed between the first stress relief layer SRL1 and the light emitting layer EML. Although FIGS. 1 and 2 illustrate embodiments in which the light emitting element LE may include the first stress relief layer SRL1 and optionally may include the second stress relief layer SRL2, the embodiments are not limited thereto. For example, the light emitting element LE may include only the second stress relief layer SRL2 without including the first stress relief layer SRL1. In one example, the light emitting element LE may include a stress relief layer SRL (also referred to as “strain relief layer” or “strain relaxation layer”) disposed between the first semiconductor layer SEM1 and the light emitting layer EML, and the stress relief layer SRL may include at least one of the first stress relief layer SRL1 or the second stress relief layer SRL2. The light emitting element LE may further include an additional stress relief layer in addition to the first stress relief layer SRL1 and the second stress relief layer SRL2.

The second stress relief layer SRL2 may be disposed on the first stress relief layer SRL1 (or the first semiconductor layer SEM1). For example, the second stress relief layer SRL2 may be disposed between the first stress relief layer SRL1 and the light emitting layer EML.

The lattice constant (for example, average lattice constant) of the second stress relief layer SRL2 may be greater than or equal to the lattice constant of the first stress relief layer SRL1 and less than or equal to the lattice constant of the light emitting layer EML. For example, the lattice constant of the second stress relief layer SRL2 may have a value between the lattice constant of the first stress relief layer SRL1 and the lattice constant of the light emitting layer EML.

In embodiments, the second stress relief layer SRL2 may contain indium. In one example, the second stress relief layer SRL2 may contain a nitride-based semiconductor material containing indium at a composition higher than the indium composition of the first stress relief layer SRL1. In an embodiment, the indium composition of the second stress relief layer SRL2 may be higher than the indium composition of the first stress relief layer SRL1, and may be less than or equal to the indium composition of the light emitting layer EML. In one example, the indium composition of the second stress relief layer SRL2 may be about 10% or more, and may be in a range of about 30% to about 100% of the indium composition of the light emitting layer EML, but is not limited thereto.

The second stress relief layer SRL2 may be a single layer or multiple layers. In one example, the second stress relief layer SRL2 may be formed as multiple layers in which second indium-containing layers including a nitride-based semiconductor material containing indium and second intermediate layers not containing indium may be sequentially or alternately stacked with each other. In one example, the second stress relief layer SRL2 may be a dummy light emitting layer formed as multiple layers of a structure that is substantially the same as or similar to that of the light emitting layer EML and containing indium at a composition less than or equal to the indium composition of the light emitting layer EML. For example, the indium composition of the second stress relief layer SRL2 may be higher than the indium composition of the first stress relief layer SRL1 and may be in the range of about 30% to about 100% of the indium composition of the light emitting layer EML. The material, indium composition and/or structure of the second stress relief layer SRL2 may vary depending on the embodiments.

By disposing the second stress relief layer SRL2 between the first stress relief layer SRL1 and the light emitting layer EML, the light emitting layer EML may be more smoothly formed. For example, the first stress relief layer SRL1, the second stress relief layer SRL2, and the light emitting layer EML with a gradually increasing indium composition and/or lattice constant may be sequentially formed on the first semiconductor layer SEM1. Accordingly, the lattice mismatch between the first semiconductor layer SEM1 and the light emitting layer EML may be more effectively mitigated, and the high-quality and/or high-efficiency light emitting element LE may be manufactured.

The second stress relief layer SRL2 may be doped or undoped. In an embodiment, the second stress relief layer SRL2 may be doped with a dopant of the first conductivity type. For example, the second stress relief layer SRL2 may include a nitride-based semiconductor material (for example, InGaN or AlInGaN) containing indium, and a first conductivity type dopant doped into the nitride-based semiconductor material. In an embodiment, the second stress relief layer SRL2 may include an n-type semiconductor layer (for example, n-InGaN or n-AlInGaN) including a nitride-based semiconductor material containing indium and doped with an n-type dopant such as Si, Ge, and Sn, but is not limited thereto.

As the second stress relief layer SRL2 is doped (for example, doped with a first conductivity type), light emission by the second stress relief layer SRL2 may be prevented or reduced. In an embodiment, the doping concentration of the second stress relief layer SRL2 (or the indium-containing layer included in the second stress relief layer SRL2) may be about 10¹⁶/cm³ or more (for example, about 10¹⁸/cm³ or more).

Accordingly, unintended light emission of the second stress relief layer SRL2 may be appropriately prevented or suppressed. For example, even if the second stress relief layer SRL2 contains indium at a composition of about 30% or more of the indium composition of the light emitting layer EML, a first conductivity type dopant doped into the second stress relief layer SRL2 may cause non-emission recombination of carriers (for example, electrons and holes), thereby preventing or reducing the generation of light in a wavelength band different from that of light generated in the light emitting layer EML within the second stress relief layer SRL2. The second stress relief layer SRL2 may be doped, so that the second stress relief layer SRL2 may be appropriately prevented from emitting light although a high current flows through the light emitting element LE. Accordingly, color mixing may be prevented and color purity of light emitted from the light emitting element LE may be increased.

In an embodiment, the doping concentration of the second stress relief layer SRL2 (or the indium-containing layer included in the second stress relief layer SRL2) may be less than or equal to the doping concentration of the first semiconductor layer SEM1. Accordingly, even if the second stress relief layer SRL2 is formed at a growth temperature less than or equal to the growth temperature of the first semiconductor layer SEM1, the high-quality second stress relief layer SRL2 with reduced defects may be formed.

The second stress relief layer SRL2 may be formed to have an appropriate thickness in consideration of at least one of the lattice matching effect, the manufacturing efficiency of the light emitting element LE, or the luminous efficiency of the light emitting element LE. For example, the second stress relief layer SRL2 (or the indium-containing layer included in the second stress relief layer SRL2) may be formed to have a thickness of about 2 nm or more to obtain a desired lattice matching effect. Although the second stress relief layer SRL2 is formed to have a thickness of about 2 nm or more, light emission of the second stress relief layer SRL2 may be suppressed by doping.

In an embodiment, the thickness of the second stress relief layer SRL2 may be formed to be less than or equal to the thickness of the light emitting layer EML. In one example, the thickness of the second stress relief layer SRL2 or each indium-containing layer constituting the second stress relief layer SRL2 may be several nanometers (for example, in a range of about 2 nm to about 5 nm), but is not limited thereto.

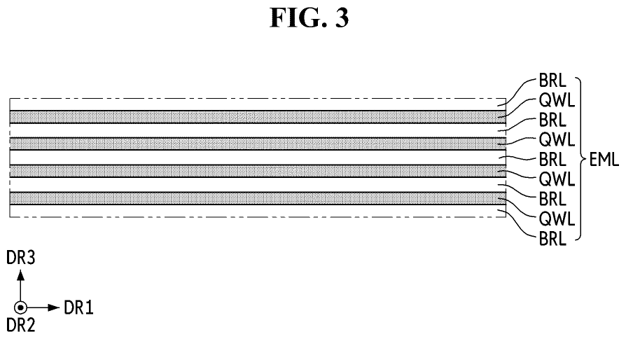

FIG. 3 is a schematic cross-sectional view showing a light emitting layer according to an embodiment. For example, FIG. 3 shows an embodiment of the light emitting layer EML shown in FIGS. 1 and 2.

Referring to FIGS. 1 to 3, the light emitting layer EML may have a single or multiple quantum well structure including at least one quantum well layer QWL. For example, the light emitting layer EML may have a multiple quantum well structure including the quantum well layers QWL and barrier layers BRL. The quantum well layers QWL and the barrier layers BRL may be alternately disposed or stacked along the third direction DR3.

In an embodiment, the respective barrier layers BRL may be disposed on the lowermost layer and the uppermost layer of the light emitting layer EML. The barrier layer BRL disposed as the lowermost layer of the light emitting layer EML may be disposed between the other layers of the light emitting layer EML and the stress relief layer SRL (for example, the first stress relief layer SRL1 or the second stress relief layer SRL2). The barrier layer BRL (for example, the barrier layer BRL of FIGS. 1 and 2) disposed as the uppermost layer of the light emitting layer EML may be disposed between the other layers of the light emitting layer EML and the electron blocking layer EBL (or the second semiconductor layer SEM2).

In an embodiment, the quantum well layer QWL may include a nitride-based semiconductor material containing indium. As an example, the quantum well layer QWL may include InGaN, but is not limited thereto.

In embodiments, the indium composition of the quantum well layer QWL may be greater than or equal to the indium composition of the second stress relief layer SRL2. In an embodiment, the indium composition of the quantum well layer QWL may be about 25% or more, and the light generated from the quantum well layer QWL may be light of a long wavelength that is equal to or longer than the green wavelength band. In an embodiment, the indium composition of the quantum well layer QWL may be about 30% or more (for example, about 35%), and the quantum well layer QWL may emit red light having a wavelength band of about 600 nm or more. The indium composition and emission wavelength of the quantum well layer QWL may be changed depending on embodiments.

The barrier layer BRL may not substantially contain indium. In an embodiment, the barrier layer BRL may include a nitride-based semiconductor material that does not include indium. As an example, the barrier layer BRL may include GaN, but is not limited thereto.

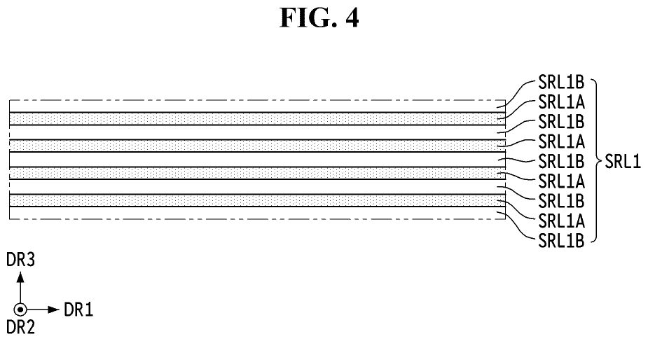

FIG. 4 is a schematic cross-sectional view showing a first stress relief layer according to an embodiment. For example, FIG. 4 shows an embodiment of the first stress relief layer SRL1 shown in FIGS. 1 and 2.

Referring to FIGS. 1 to 4, the first stress relief layer SRL1 may be formed as a single layer or multiple layers including at least one indium-containing layer (for example, an indium-containing layer with a low indium composition) containing indium. For example, the first stress relief layer SRL1 may have a multilayer structure including first indium-containing layers SRL1A and first intermediate layers SRL1B (or first barrier layers). The first indium-containing layers SRL1A and the first intermediate layers SRL1B may be alternately disposed or stacked along the third direction DR3.

The first indium-containing layer SRL1A may contain indium. For example, the first indium-containing layer SRL1A may contain a nitride-based semiconductor material (for example, InGaN or AlInGaN) containing indium.

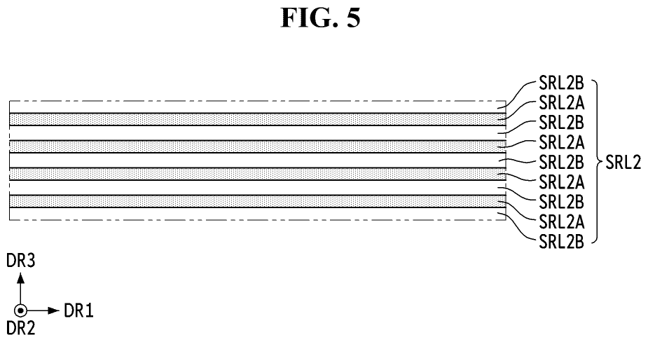

In an embodiment, the indium composition of the first indium-containing layer SRL1A may be lower than the indium composition of the second stress relief layer SRL2 (or a second indium-containing layer SRL2A of FIG. 5). For example, the indium composition of the first indium-containing layer SRL1A may be less than about 30% of the indium composition of the quantum well layer QWL. Accordingly, the first stress relief layer SRL1 including the first indium-containing layer SRL1A may be smoothly or appropriately formed on the first semiconductor layer SEM1.

The indium composition of the first indium-containing layer SRL1A may be uniform or non-uniform. For example, the indium composition of the first indium-containing layers SRL1A may be substantially the same. By way of example, the indium composition of the first indium-containing layers SRL1A may gradually change. For example, the indium composition of the first indium-containing layers SRL1A may gradually vary from the first indium-containing layer SRL1A in a lower layer portion adjacent to the first semiconductor layer SEM1 to the first indium-containing layer SRL1A in an upper layer portion adjacent to the light emitting layer EML or the second stress relief layer SRL2. For example, the indium composition of the first indium-containing layers SRL1A may gradually increase along the third direction D3, or gradually increase and decrease along the third direction D3.

In an embodiment, the first indium-containing layer SRL1A may be doped. As an example, the first indium-containing layer SRL1A may be doped with the first conductivity type and thus may include a dopant of the first conductivity type. In one example, the first indium-containing layer SRL1A may contain InGaN or AlInGaN, and may contain an n-type dopant such as Si, Ge, or Sn.

In an embodiment, the doping concentration of the first indium-containing layer SRL1A may be less than or equal to the doping concentration of the first semiconductor layer SEM1. Accordingly, the conductivity of the first indium-containing layer SRL1A and the first stress relief layer SRL1 including it may be improved while reducing defects in the first stress relief layer SRL1 and the light emitting element LE including it.

In an embodiment, each of the first indium-containing layers SRL1A may have a thickness of about 10 nm or less, for example, a thickness limited to about 5 nm or less. By forming the first indium-containing layer SRL1A with a small thickness, the first indium-containing layer SRL1A may be formed smoothly or appropriately, and the conductivity of the first indium-containing layer SRL1A and the first stress relief layer SRL1 including it may be improved or ensured.

The first intermediate layers SRL1B may not substantially contain indium. For example, the first intermediate layers SRL1B may include a nitride-based semiconductor material (for example, GaN) that does not include indium. The first intermediate layers SRL1B may be doped or undoped.

By sequentially forming (for example, growing) the first indium-containing layers SRL1A while the first intermediate layers SRL1B are formed between the first indium-containing layers SRL1A, the first indium-containing layers SRL1A may be formed more smoothly and/or appropriately. Accordingly, the high-quality and/or high-efficiency light emitting element LE with reduced defects may be manufactured.

In an embodiment, each of the first intermediate layers SRL1B may have a thickness of about 10 nm or less, for example, a thickness of about 5 nm or less. In an embodiment, each of the first indium-containing layer SRL1A and the first intermediate layer SRL1B may have a small thickness of about 5 nm or less. By having the first indium-containing layer SRL1A and the first intermediate layer SRL1B with a small thickness, the conductivity of the first stress relief layer SRL1 may be improved or ensured.

The first intermediate layers SRL1B may be doped or undoped. As an example, the first intermediate layer SRL1B may be doped with the first conductivity type or may be undoped. In an embodiment in which the first intermediate layer SRL1B is doped, the doping concentration of the first intermediate layer SRL1B may be less than or equal to the doping concentration of the first semiconductor layer SEM1. Accordingly, while the conductivity of the first intermediate layer SRL1B and the first stress relief layer SRL1 including the same is improved, defects in the first stress relief layer SRL1 and the light emitting element LE including the same may be reduced.

In an embodiment, the doping concentration of first indium-containing layer SRL1A and/or the first intermediate layers SRL1B may be uniform or non-uniform. For example, the doping concentration of the first indium-containing layer SRL1A and/or the first intermediate layers SRL1B may be uniform overall or may gradually change from the lower layer portion to the upper layer portion along the third direction DR3.

In an embodiment, the doping concentration of the first indium-containing layers SRL1A and/or the first intermediate layers SRL1B may gradually decrease from the lower layer portion to the upper layer portion. Accordingly, diffusion of the dopant of the first stress relief layer SRL1 into the light emitting layer EML may be prevented or reduced.

FIG. 5 is a schematic cross-sectional view showing a second stress relief layer according to an embodiment. For example, FIG. 5 shows an embodiment of the second stress relief layer SRL2 shown in FIG. 2.

Referring to FIGS. 1 to 5, the second stress relief layer SRL2 may be formed as a single layer or multiple layers including at least one indium-containing layer (for example, an indium-containing layer with an intermediate indium composition). For example, the second stress relief layer SRL2 may have a multilayer structure including the second indium-containing layers SRL2A and second intermediate layers SRL2B (or second barrier layers). The second indium-containing layers SRL2A and the second intermediate layers SRL2B may be alternately disposed or stacked along the third direction DR3.

The second indium-containing layer SRL2A may contain indium. For example, the second indium-containing layer SRL2A may contain a nitride-based semiconductor material (for example, InGaN or AlInGaN) containing indium.

In an embodiment, the indium composition of the second indium-containing layer SRL2A may be higher than the indium composition of the first stress relief layer SRL1 (for example, the indium composition of the first indium-containing layer SRL1A of FIG. 4) and less than or equal to the indium composition of the light emitting layer EML (for example, the indium composition of the quantum well layer QWL of FIG. 3). For example, the indium composition of the second indium-containing layer SRL2A may be in the range of about 30% to about 100% of the indium composition of the quantum well layer QWL. Accordingly, the second stress relief layer SRL2 including the second indium-containing layer SRL2A may be smoothly or appropriately formed on the first stress relief layer SRL1.

The indium composition of the second indium-containing layer SRL2A may be uniform or non-uniform. For example, the indium composition of the second indium-containing layer SRL2A may be substantially the same. By way of example, the indium composition of the second indium-containing layer SRL2A may gradually change. For example, the indium composition of the second indium-containing layers SRL2A may gradually vary from the second indium-containing layer SRL2A in a lower layer portion adjacent to the first stress relief layer SRL1 (or first semiconductor layer SEM1) to the second indium-containing layer SRL2A in an upper layer portion adjacent to the light emitting layer EML. For example, the indium composition of the second indium-containing layer SRL2A may gradually increase along the third direction D3, or gradually increase and decrease along the third direction D3.

In an embodiment, the bandgap energy of the second indium-containing layer SRL2A may have a value between the bandgap energy of the first indium-containing layer SRL1A included in the first stress relief layer SRL1 and the bandgap energy of the quantum well layer QWL included in the light emitting layer EML. For example, the quantum well layer QWL may have a bandgap energy capable of emitting light (for example, red light) in a green wavelength band to a red wavelength band, the second indium-containing layer SRL2A may have a bandgap energy capable of emitting light (for example, blue light) in a blue wavelength band to a green wavelength band, and the first indium-containing layer SRL1A may have a bandgap energy capable of emitting light (for example, ultraviolet (UV) light) in an ultraviolet wavelength band to a cyan wavelength band.

In an embodiment, the second indium-containing layer SRL2A may be doped. As an example, the second indium-containing layer SRL2A may be doped with the first conductivity type and thus may include a dopant of the first conductivity type. In one example, the second indium-containing layer SRL2A may contain InGaN or AlInGaN, and may contain an n-type dopant such as Si, Ge, or Sn.

In an embodiment, the doping concentration of the second indium-containing layer SRL2A may be about 10¹⁶/cm³ or more (for example, about 10¹⁸/cm³ or more), and may be less than or equal to the doping concentration of the first semiconductor layer SEM1. Accordingly, the conductivity of the stress relief layer SRL including at least one of the first indium-containing layer SRL1A or the second indium-containing layer SRL2A may be improved while reducing defects in the stress relief layer SRL and the light emitting element LE including the stress relief layer SRL.

In an embodiment, each of the second indium-containing layers SRL2A may have a thickness of about 10 nm or less, for example, a thickness limited to about 5 nm or less. By forming the second indium-containing layer SRL2A with a small thickness, the second indium-containing layer SRL2A may be formed smoothly or appropriately, and the conductivity of the second indium-containing layer SRL2A and the second stress relief layer SRL2 including it may be improved or ensured.

In an embodiment, the second indium-containing layer SRL2A disposed on the uppermost layer of the second stress relief layer SRL2 may be directly in contact with the light emitting layer EML. For example, the last of the second indium-containing layers SRL2A may be disposed as the uppermost layer of the second stress relief layer SRL2, and the light emitting layer EML (or the first of the barrier layers BRL disposed as the lowermost layer of the light emitting layer EML) may be disposed directly on the last second indium-containing layer SRL2A. By disposing the second indium-containing layer SRL2A in close proximity to the quantum well layer QWL on the barrier layer BRL, the lattice matching effect by the second stress relief layer SRL2 may be improved or ensured, and indium may be more smoothly injected into the quantum well layer QWL of the light emitting layer EML. The first of the second indium-containing layers SRL2A of the second stress relief layer SRL2 or the first of the second intermediate layers SRL2B of the second stress relief layer SRL2 may be disposed as the lowermost layer of the second stress relief layer SRL2.

The second intermediate layers SRL2B may not substantially contain indium. For example, the second intermediate layers SRL2B may include a nitride-based semiconductor material (for example, GaN) that does not include indium. The second intermediate layers SRL2B may be doped or undoped.

By sequentially forming (for example, growing) the second indium-containing layers SRL2A while the second intermediate layers SRL2B are formed between the second indium-containing layers SRL2A, the second indium-containing layers SRL2A may be formed more smoothly and/or appropriately. Accordingly, the high-quality and/or high-efficiency light emitting element LE with reduced defects may be manufactured.

In an embodiment, each of the second intermediate layers SRL2B may have a thickness of about 10 nm or less, for example, a thickness of about 5 nm or less. In an embodiment, each of the second indium-containing layer SRL2A and the second intermediate layer SRL2B may have a small thickness of about 5 nm or less. By having the second indium-containing layer SRL2A and the second intermediate layer SRL2B with a small thickness, the conductivity of the second stress relief layer SRL2 may be improved or ensured.

The second intermediate layers SRL2B may be doped or undoped. As an example, the second intermediate layer SRL2B may be doped with the first conductivity type or may be undoped. In an embodiment in which the second intermediate layer SRL2B is doped, the doping concentration of the second intermediate layer SRL2B may be less than or equal to the doping concentration of the first semiconductor layer SEM1 and/or the doping concentration of the first stress relief layer SRL1. Accordingly, while the conductivity of the second intermediate layer SRL2B and the second stress relief layer SRL2 including the same is improved, defects in the second stress relief layer SRL2 and the light emitting element LE including the same may be reduced.

In an embodiment, the doping concentration of second indium-containing layer SRL2A and/or the second intermediate layers SRL2B may be uniform or non-uniform. For example, the doping concentration of the second indium-containing layer SRL2A and/or the second intermediate layers SRL2B may be uniform overall or may gradually change from the lower layer portion to the upper layer portion along the third direction DR3.

In an embodiment, the doping concentration of the second indium-containing layers SRL2A and/or the second intermediate layers SRL2B may gradually decrease from the lower layer portion to the upper layer portion. Accordingly, diffusion of the dopant of the second stress relief layer SRL2 into the light emitting layer EML may be prevented or reduced.

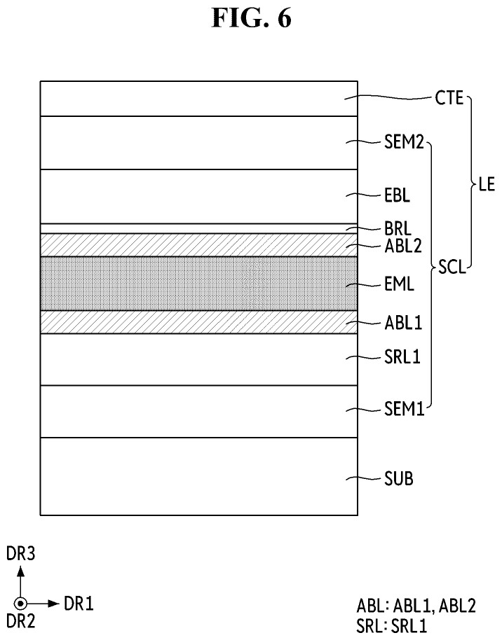

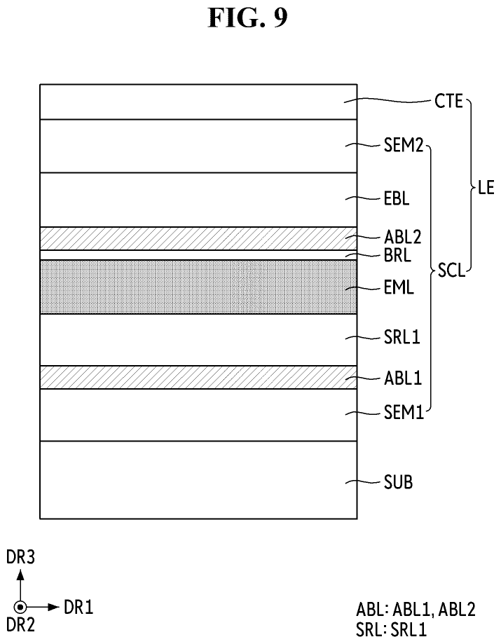

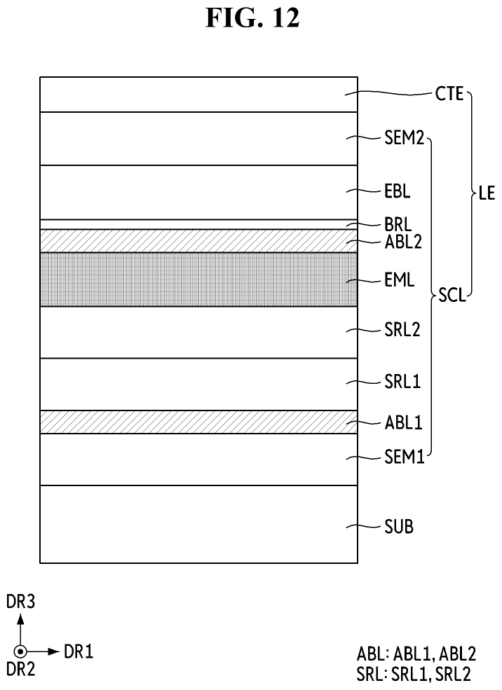

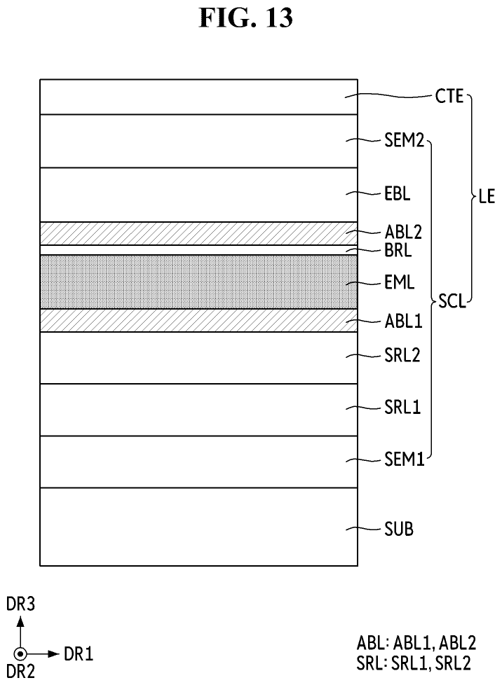

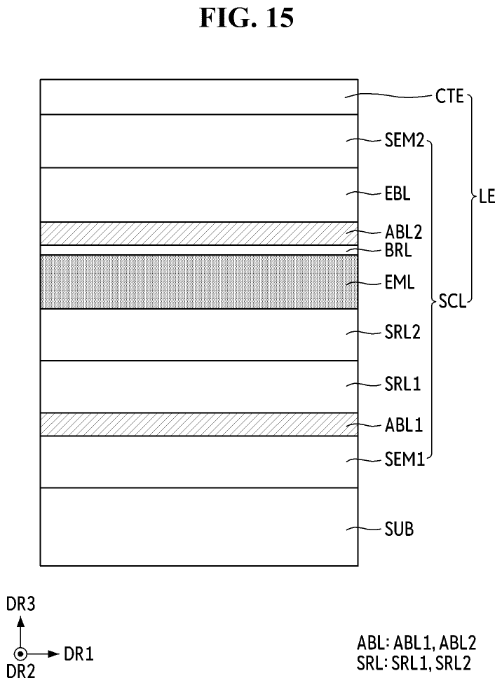

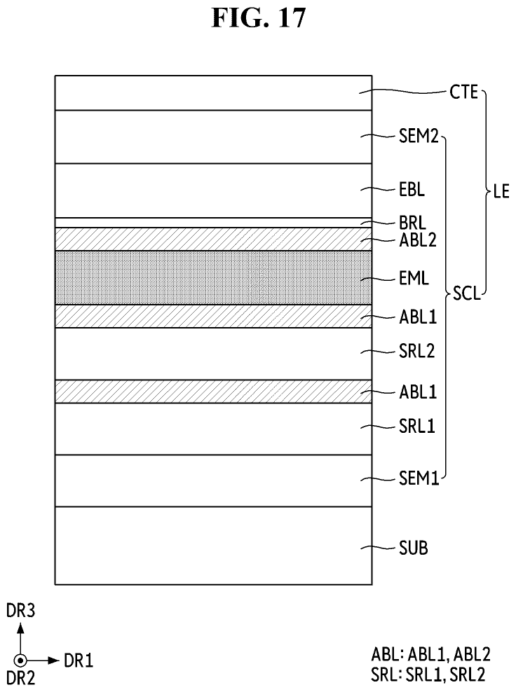

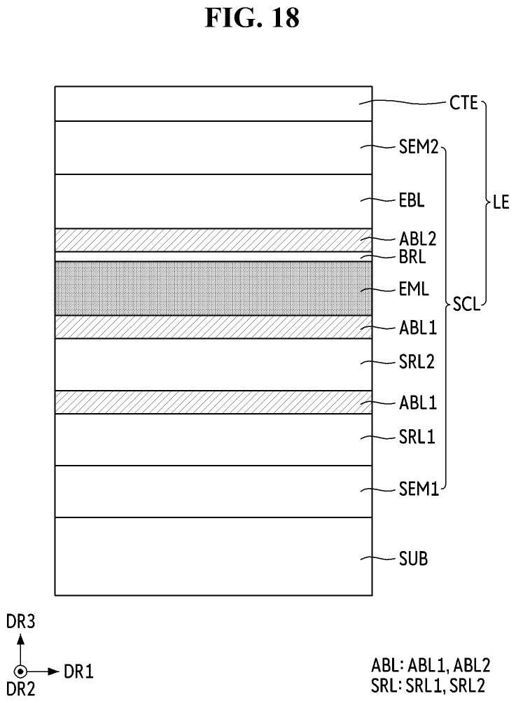

FIGS. 6 to 18 are schematic cross-sectional views showing light emitting elements according to embodiments. For example, FIGS. 6 to 18 illustrate various embodiments of each light emitting element LE including at least one stress relief layer SRL as in the embodiments of FIGS. 1 and 2, and further including at least one absorption layer ABL. FIGS. 6 to 18 illustrate different embodiments with respect to the stress relief layer SRL and the absorption layer ABL.

Referring to FIGS. 6 to 18 in addition to FIGS. 1 to 5, the light emitting element LE according to an embodiment may further include the absorption layer ABL disposed at least one of below or above the light emitting layer EML. For example, the light emitting element LE may further include at least one of a first absorption layer ABL1 disposed below the light emitting layer EML or a second absorption layer ABL2 disposed above the light emitting layer EML (or the last quantum well layer QWL of the light emitting layer EML).

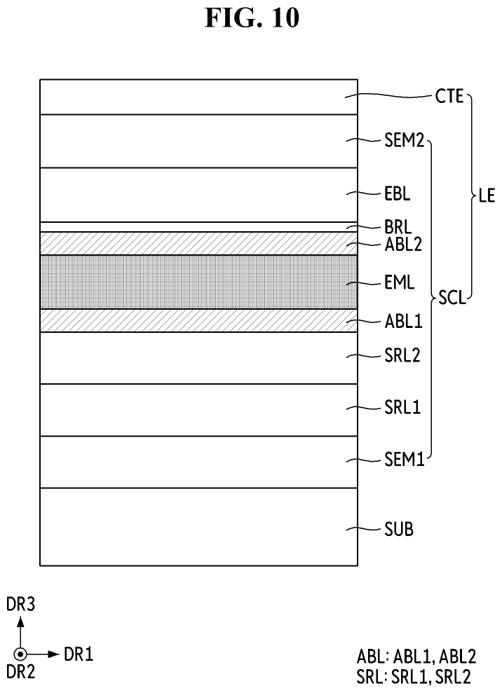

FIGS. 6 to 9 illustrate various embodiments of the light emitting element LE including the first stress relief layer SRL1, the first absorption layer ABL1, and the second absorption layer ABL2. FIGS. 10 to 18 illustrate various embodiments of the light emitting element LE including the first stress relief layer SRL1, the second stress relief layer SRL2, the first absorption layer ABL1, and/or the second absorption layer ABL2.

Embodiments of the light emitting element LE including the stress relief layer SRL and the absorption layer ABL are not limited to the embodiments shown in FIGS. 6 to 18, and all possible combinations of embodiments may fall within the scope of the disclosure. In addition, FIGS. 6 to 18 disclose the light emitting element LE including at least two absorption layers ABL according to embodiments, but the light emitting element LE according to an embodiment may include only one absorption layer ABL (for example, the first absorption layer ABL1 or the second absorption layer ABL2). FIGS. 6 to 18 disclose the light emitting element LE including the first stress relief layer SRL1 and optionally including the second stress relief layer SRL2 according to embodiments, but the light emitting element LE according to an embodiment may include only the second stress relief layer SRL2 without including the first stress relief layer SRL1. For example, the embodiments may include all possible combinations of embodiments related to the light emitting element LE including at least one stress relief layer SRL and at least one absorption layer ABL.

The first absorption layer ABL1 may be disposed between the first semiconductor layer SEM1 and the light emitting layer EML (or the first quantum well layer QWL of the light emitting layer EML). For example, the first absorption layer ABL1 may be disposed at least one of between the stress relief layer SRL and the light emitting layer EML, between the first semiconductor layer SEM1 and the stress relief layer SRL, or between the first stress relief layer SRL1 and the second stress relief layer SRL2 included in the stress relief layer SRL.

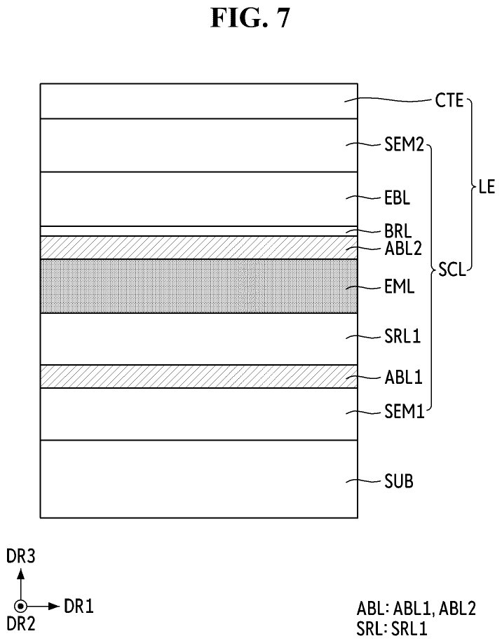

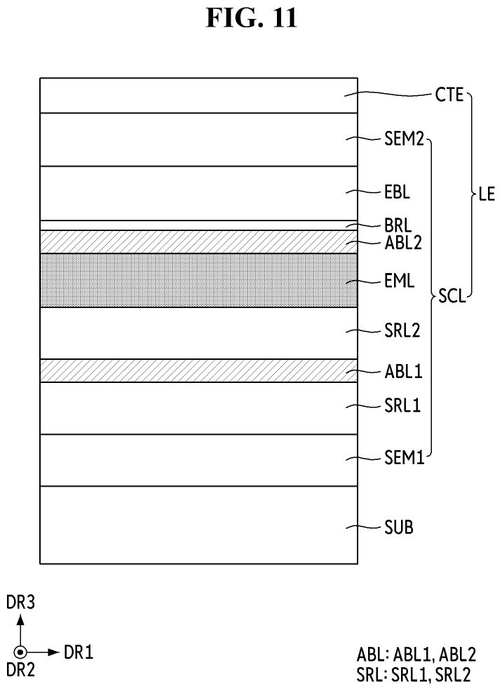

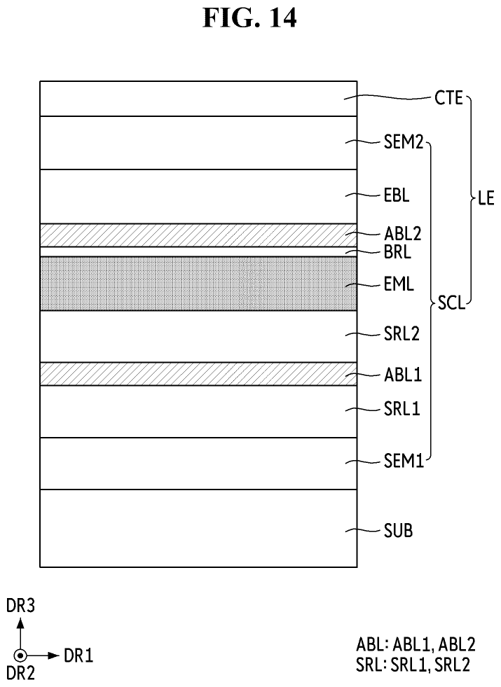

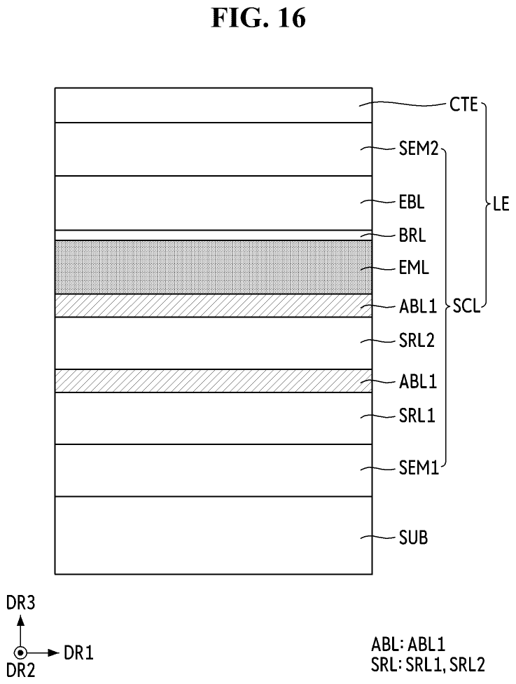

In one example, the first absorption layer ABL1 may be disposed between the stress relief layer SRL and the light emitting layer EML as shown in FIGS. 6, 8, 10, and 13, between the first semiconductor layer SEM1 and the stress relief layer SRL as shown in FIGS. 7, 9, 12, and 15, or between the first stress relief layer SRL1 and the second stress relief layer SRL2 included in the stress relief layer SRL as shown in FIGS. 11 and 14. By way of example, as shown in FIGS. 16, 17, and 18, each of the first absorption layers ABL1 may be disposed between the stress relief layer SRL and the light emitting layer EML, and between the first stress relief layer SRL1 and the second stress relief layer SRL2.

The second absorption layer ABL2 may be disposed between the light emitting layer EML (or the last quantum well layer QWL of the light emitting layer EML) and the second semiconductor layer SEM2. For example, the second absorption layer ABL2 may be disposed between the light emitting layer EML (or the last quantum well layer QWL of the light emitting layer EML) and the electron blocking layer EBL.

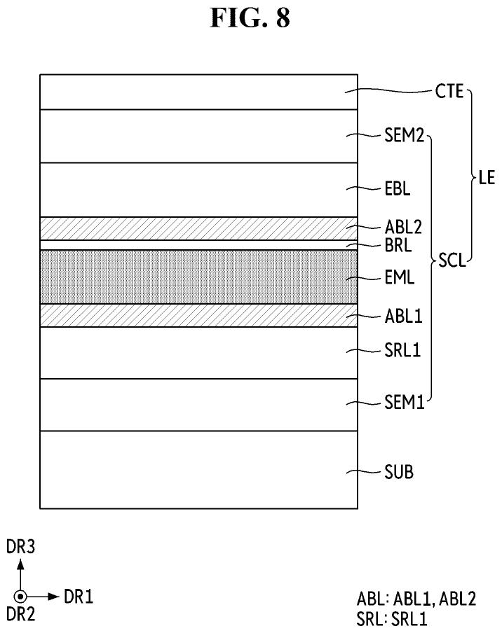

In one example, the second absorption layer ABL2 may be disposed between the last quantum well layer QWL of the light emitting layer EML and the last barrier layer BRL of the light emitting layer EML as shown in FIGS. 6, 7, 10, 11, 12, and 17, or may be disposed on top of the last barrier layer BRL of the light emitting layer EML (for example, between the last barrier layer BRL of the light emitting layer EML and the electron blocking layer EBL) as shown in FIGS. 8, 9, 13, 14, 15, and 18. By way of example, the light emitting element LE may, as shown in FIG. 16, include only at least one first absorption layer ABL1 disposed below the light emitting layer EML without including the second absorption layer ABL2, or conversely, it may include only at least one second absorption layer ABL2 disposed above the light emitting layer EML (or the last quantum well layer QWL of the light emitting layer EML) without including the first absorption layer ABL1.

The absorption layer ABL absorbs light in a wavelength band corresponding to the bandgap energy of the stress relief layer SRL. For example, the absorption layer ABL may be formed of a material and/or thickness capable of absorbing light that may be generated in the stress relief layer SRL (for example, light resulting from the light emission recombination of carriers generated in the stress relief layer SRL and having a different wavelength band from the light generated in the light emitting layer EML).

In an embodiment, the absorption layer ABL may include a nitride-based semiconductor material containing indium. For example, the absorption layer ABL may contain InGaN or AlInGaN. The indium composition of the absorption layer ABL may be higher than the indium composition of the stress relief layer SRL and lower than the indium composition of the light emitting layer EML. For example, the indium composition of the absorption layer ABL may be higher than the indium composition of the indium-containing layer (for example, the first indium-containing layer SRL1A and/or the second indium-containing layer SRL2A) included in the stress relief layer SRL and lower than the indium composition of the quantum well layer QWL included in the light emitting layer EML. In one example, in case that the indium composition of the second stress relief layer SRL2 is in the range of about 10% to about 25% and the indium composition of the light emitting layer EML is about 35% or more, the indium composition of the absorption layer ABL may be in the range of about 25% to about 35% (for example, an intermediate value in the range of about 25% to about 35%).

In an embodiment, the bandgap energy of the absorption layer ABL may have a value between the bandgap energy of the stress relief layer SRL and the bandgap energy of the light emitting layer EML. For example, the bandgap energy of the absorption layer ABL may have a value between the bandgap energy of the indium-containing layer included in the stress relief layer SRL and the bandgap energy of the quantum well layer QWL included in the light emitting layer EML. In one example, the bandgap energy of the absorption layer ABL may be lower than the bandgap energy of the first indium-containing layer SRL1A and/or the second indium-containing layer SRL2A and higher than the bandgap energy of the quantum well layer QWL.

In an embodiment, each absorption layer ABL may have a thickness and/or structure capable of preventing or suppressing the light emission recombination of carriers in the absorption layer ABL. For example, each absorption layer ABL may be formed as a single layer with a thickness suitable to prevent or suppress the light emission recombination of the carriers. In an embodiment, each absorption layer ABL may be a single layer (for example, a single bulk layer containing InGaN or AlInGaN) having a thickness of about 10 nm or more and containing indium. In one example, the thickness of each absorption layer ABL may be in the range of about 10 nm to about 100 nm. Accordingly, the absorption layer ABL may be smoothly formed and the light emission of the absorption layer ABL may be prevented. However, the thickness of the absorption layer ABL is not limited to the described range, and the thickness of the absorption layer ABL may be appropriately adjusted depending on the characteristics of the light emitting element LE, the manufacturing efficiency, and the like within the spirit and the scope of the disclosure.

The absorption layer ABL may absorb light (for example, short-wavelength light unintentionally generated in the stress relief layer SRL) emitted from the stress relief layer SRL and may not absorb light (for example, long-wavelength light with a wavelength band longer than that of the light generated in the stress relief layer SRL) of the first color emitted from the light emitting layer EML. For example, light of the first color (for example, red light or green light) emitted from the light emitting layer EML may pass through the absorption layer ABL, and light of another color (for example, short-wavelength light with a wavelength band shorter than that of the red light or green light) emitted from the stress relief layer SRL may be absorbed and extinguished by the absorption layer ABL As the absorption layer ABL functions as a color filter that absorbs light emitted from the stress relief layer SRL, the light emitting element LE itself may emit light of the first color with high color purity.

The absorption layer ABL may be doped or undoped. In an embodiment, the absorption layer ABL may be doped with a first conductivity type or a second conductivity type. For example, the first absorption layer ABL1 may be doped with a first conductivity type and include a first conductivity type dopant, while the second absorption layer ABL2 may be doped with a second conductivity type and include a second conductivity type dopant.

In an embodiment, the doping concentration of the first conductivity type dopant or the second conductivity type dopant included in each absorption layer ABL may be about 10¹⁸/cm³ or more. As a result, the light emission recombination of carriers in the absorption layer ABL may be more effectively prevented. As the light emission of the absorption layer ABL is prevented, unintended light may be prevented from being generated from the light emitting element LE, and the color purity of the light emitted from the light emitting element LE may be increased.

As described above, the light emitting element LE according to embodiments may include the stress relief layer SRL disposed between the first semiconductor layer SEM1 and the light emitting layer EML. Consequently, the high-quality light emitting layer EML may be smoothly and/or appropriately formed on the first semiconductor layer SEM1. For example, according to embodiments, the light emitting element LE having a high indium composition of the light emitting layer EML and long-wavelength emission may also be appropriately or readily formed.

In addition, the light emitting element LE according to embodiments may further include the absorption layer ABL disposed above and/or below the light emitting layer EML and absorbing light in a wavelength band corresponding to the bandgap energy of the stress relief layer SRL. The absorption layer ABL may transmit light in a wavelength band generated in the light emitting layer EML and absorb light in a different wavelength band generated in the stress relief layer SRL. For example, even in case that a high current flows through the light emitting element LE in response to a driving signal (for example, a high grayscale data signal) corresponding to a high current, even if light in a different wavelength band (for example, light of a different wavelength band and/or color from the light of the first color generated in the light emitting layer EML) is generated in the stress relief layer SRL due to the high current, the light in the different wavelength band may be absorbed and extinguished by the absorption layer ABL. Accordingly, the color purity of the light (for example, the light of the first color emitted from the light emitting layer EML) emitted from the light emitting element LE itself may be increased. In addition, since only light of the first color is selectively emitted from the light emitting element LE, the luminance and color purity of the light of the first color may be improved.

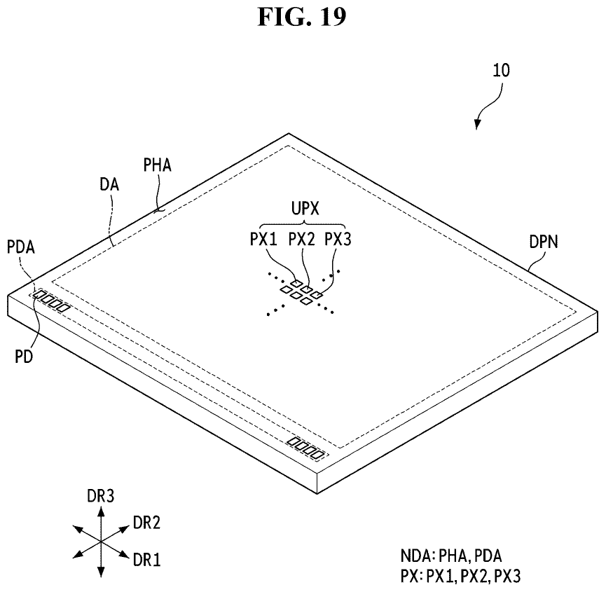

FIG. 19 is a schematic perspective view illustrating a display device according to an embodiment. For example, FIG. 19 illustrates an example of a light emitting display device that may include the light emitting element LE according to at least one of the embodiments described above.

Referring to FIG. 19 in addition to FIGS. 1 to 18, a display device 10 is a device for displaying a moving image or a still image, and may be used as a display screen for various products. For example, the display device 10 may be used as a display screen for various products such as televisions, laptop computers, monitors, billboards and the Internet of Things (IoT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs). The display device 10 may be applied to a virtual reality (VR) device, an augmented reality (AR) device, or the like within the spirit and the scope of the disclosure.

The display device 10 may include a display panel DPN including a display area DA and a non-display area NDA. In an embodiment, the display panel DPN may have a quadrilateral planar shape, but is not limited thereto. For example, the display panel DPN may have a polygonal shape other than a quadrilateral shape, a circular shape, an elliptical shape, or an irregular shape in plan view. In FIG. 1, the first direction DR1, the second direction DR2, and the third direction DR3 are indicated. In an embodiment, the first direction DR1, the second direction DR2, and the third direction DR3 may be the horizontal direction, the vertical direction, and the thickness direction of the display panel DPN, respectively.

The display device 10 may include pixels PX disposed in the display area DA. An image may be displayed in the display area DA by the pixels PX. For example, the pixels PX and wires (or some of the wires) connected to the pixels PX may be disposed in the display area DA. In describing embodiments, the term “connect” may include electrical connection and/or physical connection. Although FIG. 19 illustrates an embodiment in which the planar shape of the display area DA is quadrilateral, the shape of the display area DA is not limited thereto.

The pixels PX may have a quadrilateral planar shape such as a rectangular shape or a rhombic shape, but the disclosure is not limited thereto. For example, the pixels PX may have another polygonal shape (for example, a hexagonal shape or diamond shape), a circular shape, an elliptical shape, or other planar shapes.

In an embodiment, the pixels PX may include first pixels PX1 (for example, first color sub-pixels) that emit light of a first color, second pixels PX2 (for example, second color sub-pixels) that emit light of a second color, and third pixels PX3 (for example, third color sub-pixels) that emit light of a third color. In an embodiment, the first color may be red, the second color may be green, and the third color may be blue, but they are not limited thereto. At least one first pixel PX1, at least one second pixel PX2, and at least one third pixel PX3 adjacent to each other may each constitute a unit pixel UPX. In each unit pixel UPX, light of the first color, light of the second color, or light of the third color may be emitted alone, or a mixture of at least two of light of the first color, light of the second color, or light of the third color may be emitted. Accordingly, the unit pixel UPX may emit light of various colors. The number, type, and/or arrangement structure of the pixels PX constituting the unit pixel UPX may vary depending on the embodiments.

Each pixel PX may include at least one light emitting element LE. Each light emitting element LE may have a circular shape, an elliptical shape, a quadrilateral shape, a polygonal shape (for example, a hexagonal shape or a rhombic shape) other than a quadrilateral shape, or other planar shapes. For example, the planar shape of the light emitting elements LE may be variously changed according to embodiments.

In an embodiment, the pixels PX may include the light emitting elements LE that emit light of different colors. For example, the first pixels PX1, the second pixels PX2, and the third pixels PX3 may include the light emitting elements LE that emit light of the first color, light of the second color, and light of the third color, respectively. However, the embodiments are not limited thereto. For example, the first pixels PX1, the second pixels PX2, and the third pixels PX3 may include the light emitting elements LE that emit light of the same color, and light conversion patterns (for example, wavelength conversion patterns including quantum dots) and/or color filters may be disposed in the emission areas of the first pixels PX1, the second pixels PX2, and/or the third pixels PX3 to convert or control the color of light emitted from the light emitting elements LE disposed in each of the pixels PX.

In an embodiment, at least one pixel PX may include the light emitting element LE according to at least one of the previously described embodiments. For example, each of the first pixels PX1 may include the light emitting element LE including the stress relief layer SRL and the absorption layer ABL as in at least one of the embodiments described in FIGS. 6 to 18. The pixels PX may include light emitting elements LE of substantially the same size, or may include light emitting elements LE of different sizes. For example, the first pixels PX1, the second pixels PX2, and the third pixels PX3 may include the light emitting elements LE having substantially the same size, or may include the light emitting elements LE having different sizes.

The pixels PX may include light emitting elements LE having substantially the same structure, or may include the light emitting elements LE having different structures. For example, each of the first pixels PX1, second pixels PX2, and third pixels PX3 may include the light emitting element LE including the stress relief layer SRL and the absorption layer ABL. By way of example, some of the first pixels PX1, the second pixels PX2, and the third pixels PX3 (for example, the first pixels PX1) may include the respective light emitting elements LE including the stress relief layer SRL and the absorption layer ABL, and some others of the first pixels PX1, the second pixels PX2, and the third pixels PX3 (for example, the second pixels PX2 and/or the third pixels PX3) may include the respective light emitting elements LE that do not include the stress relief layer SRL and/or the absorption layer ABL.

The non-display area NDA may be an area where an image is not displayed. The non-display area NDA may be disposed around the display area DA. In one example, the non-display area NDA may be disposed at the edge of the display panel DPN to surround the display area DA.

The non-display area NDA may include a pad area PDA and a peripheral area PHA. Wires (or portions of the wires) connected to the pixels PX, and pads PD may be disposed in the non-display area NDA. In an embodiment, the non-display area NDA may further include a common voltage supply area disposed around the display area DA, for example, between the display area DA and the pad area PDA.

The pads PD may be disposed in the pad area PDA. The pads PD may be connected to an external circuit board. For example, the pads PD may be electrically connected to circuit pads on the circuit board through a conductive connection member such as a wire. In addition, the pads PD may be electrically connected to the pixels PX. For example, the pads PD may include signal pads and power pads that are electrically connected to the light emitting elements LE and pixel circuits of the pixels PX. In an embodiment, the pixels PX and the pads PD may be electrically connected to each other through circuit elements and/or wires formed on a semiconductor circuit board or the like of the display panel DPN. Through the pads PD, driving signals and driving voltages for driving the pixels PX may be supplied from the external circuit board to the display device 10 (or the display panel DPN). A driving circuit that generates the driving signals supplied to the pixels PX may be disposed inside the display panel DPN or outside the display panel DPN (for example, on a circuit board electrically connected to the display panel DPN).

The peripheral area PHA may be the remaining area excluding the pad area PDA in the non-display area NDA. The peripheral area PHA may surround the display area DA. Wires that connect the pixels PX to the pads PD may pass through the peripheral area PHA.

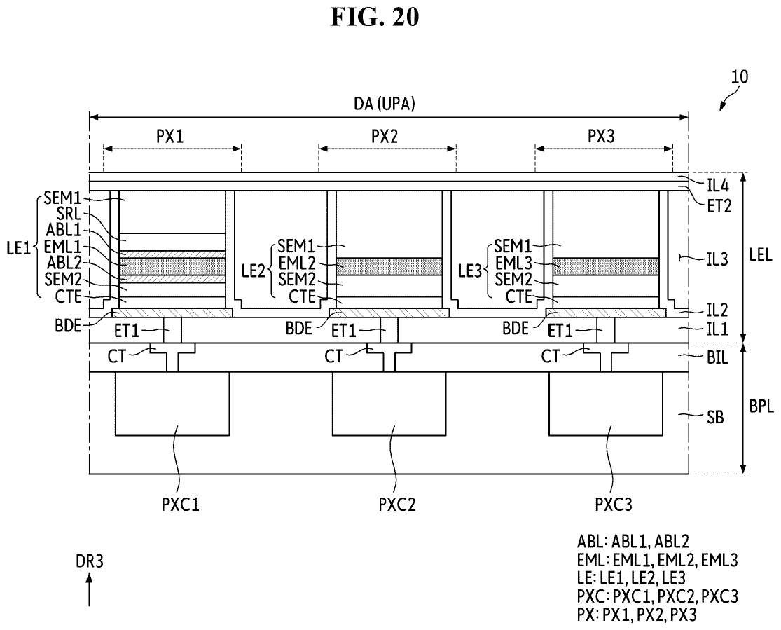

FIG. 20 is a schematic cross-sectional view showing a display device according to an embodiment. For example, FIG. 20 shows a portion of the display area DA of FIG. 19, illustrating a schematic cross section of the first pixel PX1, the second pixel PX2, and the third pixel PX3 disposed in one unit pixel area UPA among the pixels PX in the display area DA. The first pixel PX1, the second pixel PX2, and the third pixel PX3 may emit light of the first color, light of the second color, and light of the third color, respectively, and may form one unit pixel UPX.

Referring to FIG. 20 in addition to FIGS. 1 to 19, the display device 10 may include a lower substrate BPL (or a thin film transistor substrate) and a light emitting element layer LEL disposed on the lower substrate BPL. FIG. 20 shows the display device 10 with a light emitting diode-on-silicon (LEDoS) structure in which light emitting diodes are disposed as the light emitting elements LE on the lower substrate BPL (for example, a backplane substrate formed as a semiconductor circuit board) formed by a semiconductor process using a silicon wafer. However, the embodiments are not limited thereto. For example, the lower substrate BPL may be a backplane substrate of a different type or structure. In addition, the embodiments may be applied to display devices of other types and/or structures, or may be applied to devices of other types and/or structures, such as lighting devices.

In an embodiment, the display device 10 may further include an additional component. In one example, the display device 10 may further include at least one of a color filter layer, a protective layer, or an optical structure (for example, a micro lens overlapping the light emitting element LE of each pixel PX) disposed on the light emitting element layer LEL.

The lower substrate BPL may include a base substrate SB, pixel circuits PXC of the pixels PX, the pads PD of FIG. 19, and the like within the spirit and the scope of the disclosure. In an embodiment, the lower substrate BPL may further include contact terminals CT and a lower insulating layer BIL (or a first capping layer) disposed on the pixel circuits PXC. Although FIG. 20 illustrates only one lower insulating layer BIL disposed on the pixel circuits PXC and surrounding the contact terminals CT, the embodiments are not limited thereto. For example, insulating layers and conductive layers may be disposed on the base substrate SB on which the pixel circuits PXC are formed.

The lower substrate BPL may further include wires electrically connected to the pixels PX and the pads PD. For example, the lower substrate BPL may include scanning lines, data lines, a first power line, and a second power line that are electrically connected to the pixels PX. In an embodiment, the first power line may be electrically connected to the pixel circuits PXC in the display area DA, and the second power line may be electrically connected to a second electrode ET2 in the display area DA and/or the peripheral area PHA. The first power line may receive a first driving voltage through at least one pad PD located in the pad area PDA, and may transmit the first driving voltage to the pixels PX (for example, the pixel circuits PXC of the pixels PX). The second power line may receive a second driving voltage through at least one other pad PD located in the pad area PDA and may transmit the second driving voltage to the pixels PX (for example, the light emitting elements LE of the pixels PX). In an embodiment, one of the first and second driving voltages may be a high potential pixel voltage (for example, an anode voltage), and the other of the first and second driving voltages may be a low potential pixel voltage (for example, a cathode voltage or a common voltage). The pixel circuits PXC, the contact terminals CT, the wires, and the pads PD may be disposed or formed on the base substrate SB.

In an embodiment, the lower substrate BPL may be formed through a semiconductor process using a silicon wafer. For example, the base substrate SB may be a silicon wafer. In an embodiment, the base substrate SB may be made of monocrystalline silicon.

The pixel circuits PXC may be disposed on the lower substrate BPL to correspond to the respective pixel areas where the respective pixels PX are disposed. In an embodiment, each of the pixel circuits PXC may include a complementary metal oxide semiconductor (CMOS) circuit formed using a semiconductor process. For example, each of the pixel circuits PXC may include at least one transistor and at least one capacitor formed through a semiconductor process.

In an embodiment, each pixel PX may include the pixel circuit PXC and at least one light emitting element LE electrically connected to the pixel circuit PXC. For example, the first pixel PX1 may include a first pixel circuit PXC1 and a first light emitting element LE1 electrically connected to the first pixel circuit PXC1. The second pixel PX2 may include a second pixel circuit PXC2 and a second light emitting element LE2 electrically connected to the second pixel circuit PXC2. The third pixel PX3 may include a third pixel circuit PXC3 and a third light emitting element LE3 electrically connected to the third pixel circuit PXC3. The first pixel circuit PXC1, the second pixel circuit PXC2, and the third pixel circuit PXC3 may control a driving current flowing through the first light emitting element LE1, the second light emitting element LE2, and the third light emitting element LE3 in response to respective driving signals inputted from the outside.

The contact terminals CT and the lower insulating layer BIL may be disposed on the pixel circuits PXC. The contact terminals CT (or portions of the pixel circuits PXC) may be exposed on the top surface of the lower substrate BPL and surrounded by the lower insulating layer BIL. The contact terminals CT may be in contact with and/or electrically connected to first electrodes ET1 (for example, first pixel electrodes or anode electrodes) of the pixels PX at the exposed portions.

The contact terminals CT may electrically connect the pixel circuits PXC to the respective first electrodes ET1. For example, the contact terminal CT electrically connected to the first pixel circuit PXC1 of the first pixel PX1 may be electrically connected to the first electrode ET1 of the first pixel PX1, the contact terminal CT electrically connected to the second pixel circuit PXC2 of the second pixel PX2 may be electrically connected to the first electrode ET1 of the second pixel PX2, and the contact terminal CT electrically connected to the third pixel circuit PXC3 of the third pixel PX3 may be electrically connected to the first electrode ET1 of the third pixel PX3. The contact terminals CT may receive the first driving voltage from the respective pixel circuits PXC.

In an embodiment, the contact terminals CT may be electrically connected to the respective light emitting elements LE through the respective first electrodes ET1 and respective bonding electrodes BDE. For example, the contact terminal CT electrically connected to the first pixel circuit PXC1 of the first pixel PX1 may be electrically connected to the first light emitting element LE1 of the first pixel PX1 through the first electrode ET1 and the bonding electrode BDE of the first pixel PX1, the contact terminal CT electrically connected to the second pixel circuit PXC2 of the second pixel PX2 may be electrically connected to the second light emitting element LE2 of the second pixel PX2 through the first electrode ET1 and the bonding electrode BDE of the second pixel PX2, and the contact terminal CT electrically connected to the third pixel circuit PXC3 of the third pixel PX3 may be electrically connected to the third light emitting element LE3 of the third pixel PX3 through the first electrode ET1 and the bonding electrode BDE of the third pixel PX3.

Although FIG. 20 illustrates the contact terminals CT and the pixel circuits PXC in separate configurations, the embodiments are not limited thereto. For example, the contact terminals CT may be portions of the respective pixel circuits PXC. In one example, the contact terminals CT may be exposed electrodes (or wires) protruding from the top surfaces of the respective pixel circuits PXC.

The contact terminals CT may include a conductive material. For example, the contact terminals CT may include, but not limited to, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof.

The lower insulating layer BIL may surround the contact terminals CT. In one example, the lower insulating layer BIL may be disposed on the base substrate SB and the pixel circuits PXC and may surround the side surfaces of the contact terminals CT.

The lower insulating layer BIL may include openings corresponding to the contact terminals CT. In one example, the lower insulating layer BIL may be opened to expose the top surfaces of the contact terminals CT.

The lower insulating layer BIL may include at least one insulating material and may have a single-layer or multilayer structure. In an embodiment, the lower insulating layer BIL may include at least one inorganic insulating layer including an inorganic insulating material (for example, silicon oxide (SiOₓ), silicon nitride (SiNₓ), aluminum oxide (AlₓO_{y}), titanium oxide (TiₓO_{y}), hafnium oxide (HfOₓ), or another inorganic insulating material).

The light emitting element layer LEL may include the light emitting elements LE and the electrodes and/or wires electrically connected to the light emitting elements LE. In addition, the light emitting element layer LEL may further include insulating layers disposed around the light emitting elements LE.

In an embodiment, the electrodes of the light emitting element layer LEL may include the first electrodes ET1 and the second electrode ET2 electrically connected to both ends of the light emitting elements LE, and the bonding electrodes BDE (or connection electrodes) electrically connected between the respective light emitting elements LE and the respective first electrodes ET1. FIG. 20 illustrates the display device 10 with a structure in which the bonding electrodes BDE are disposed above the lower insulating layer BIL, and the light emitting elements LE are bonded to the lower substrate BPL by the bonding electrodes BDE, but the structure of the display device 10 according to embodiments is not limited thereto. For example, the light emitting elements LE may be appropriately disposed above the lower substrate BPL using other connection electrodes or wires without using a bonding method.

In an embodiment, the insulating layers of the light emitting element layer LEL may include a first insulating layer IL1, a second insulating layer IL2, a third insulating layer IL3, and a fourth insulating layer IL4 (or a second capping layer) sequentially disposed on the lower substrate BPL. Each of the insulating layers of the light emitting element layer LEL may be constituted with a single layer or multiple layers including at least one insulating material. In an embodiment, each of the insulating layers of the light emitting element layer LEL may include an inorganic insulating layer including an inorganic insulating material (for example, silicon oxide (SiOₓ), silicon nitride (SiNₓ), silicon oxynitride (SiOₓN_{y}), silicon oxycarbide (SiOₓC_{y}), aluminum oxide (AlₓO_{y}), aluminum nitride (AlNₓ), zirconium oxide (ZrOₓ), hafnium oxide (HfOₓ), titanium oxide (TiOₓ), or another inorganic insulating material).

The first electrodes ET1 and the first insulating layer IL1 may be disposed on the lower substrate BPL. For example, the first electrodes ET1 may be disposed on the respective contact terminals CT, and the first insulating layer IL1 may cover the lower substrate BPL and surround the first electrodes ET1.

The first electrodes ET1 may include a conductive material. For example, the first electrodes ET1 may include at least one of gold (Au), copper (Cu), tin (Sn), titanium (Ti), aluminum (Al), silver (Ag), or other metals.

The first electrodes ET1 may be disposed between the lower substrate BPL and the bonding electrodes BDE to connect the lower substrate BPL to the bonding electrodes BDE. For example, the first electrode ET1 of each pixel PX may be electrically connected between the contact terminal CT and the bonding electrode BDE of the corresponding pixel PX. The first electrodes ET1 may penetrate the first insulating layer IL1. In FIG. 20, the first electrodes ET1 and the bonding electrodes BDE are illustrated as separate elements, but the embodiments are not limited thereto. For example, the bonding electrodes BDE may be considered as portions of the respective first electrodes ET1.

The first insulating layer IL1 may be disposed on the lower substrate BPL. The first insulating layer IL1 may include openings corresponding to the first electrodes ET1 and may surround the side surfaces of the first electrodes ET1. In one example, the first insulating layer IL1 may be opened to expose the top surfaces of the first electrodes ET1.

The bonding electrodes BDE may be disposed on the first electrodes ET1 and the first insulating layer IL1. For example, the bonding electrodes BDE may be disposed on the respective first electrodes ET1 and may be disposed on a portion of the first insulating layer IL1 around the first electrodes ET1.

The bonding electrodes BDE may be disposed between the respective first electrodes ET1 and the respective light emitting elements LE. The bonding electrodes BDE may be electrically connected between the respective first electrodes ET1 and the respective light emitting elements LE (for example, the contact electrodes CTE or the second semiconductor layer SEM2 of the respective light emitting elements LE).

The bonding electrodes BDE may include a conductive material. In an embodiment, the bonding electrodes BDE may include a bonding metal layer containing at least one metal (for example, eutectic metal) suitable for a bonding process and may optionally further include a reflective layer containing a metal, such as aluminum (Al), having a high reflectivity. The material or structure of the bonding electrodes BDE may be variously changed according to embodiments.

In an embodiment, the bonding electrodes BDE may have a larger area than the light emitting elements LE. For example, the bonding electrodes BDE may protrude outward from the light emitting elements LE in case that viewed in a plan view.

The light emitting elements LE may be disposed on the respective bonding electrodes BDE. For example, the light emitting element LE of each of the pixels PX may be disposed or bonded onto the bonding electrode BDE of the corresponding pixel PX, and may be electrically connected to the first electrode ET1 and the pixel circuit PXC of the corresponding pixel PX through the bonding electrode BDE.

Each of the light emitting elements LE may include the first semiconductor layer SEM1 and the second semiconductor layer SEM2 overlapping each other, and the light emitting layer EML disposed between the first semiconductor layer SEM1 and the second semiconductor layer SEM2. In an embodiment, each of the light emitting elements LE may further include the above-described electron blocking layer EBL and the like within the spirit and the scope of the disclosure. In an embodiment, the light emitting layer EML may include the quantum well layer QWL including a nitride-based semiconductor material containing indium. The quantum well layer QWL may contain indium in a composition corresponding to the emission wavelength of each of the light emitting elements LE.

In an embodiment, each of the light emitting elements LE may further include the contact electrode CTE. The contact electrode CTE may be disposed on the bonding electrode BDE of the corresponding pixel PX to be electrically connected to the bonding electrode BDE. FIG. 20 illustrates an embodiment in which each light emitting element LE may include only the contact electrode CTE covering one surface or a surface (for example, the bottom surface) of the second semiconductor layer SEM2, but the embodiments are not limited thereto. In one example, each light emitting element LE may further include an additional contact electrode disposed between the first semiconductor layer SEM1 and the second electrode ET2 while covering one surface or a surface (for example, the top surface) of the first semiconductor layer SEM1.

In an embodiment, the first light emitting element LE1, the second light emitting element LE2, and the third light emitting element LE3 may emit light of different colors. For example, the first light emitting element LE1, the second light emitting element LE2, and the third light emitting element LE3 may emit light of the first color (for example, red light), light of the second color (for example, green light), and light of the third color (for example, blue light), respectively. The light emitting layer EML (hereinafter referred to as “first light emitting layer EML1”) of the first light emitting element LE1, the light emitting layer EML (hereinafter referred to as a “second light emitting layer EML2”) of the second light emitting element LE2, and the light emitting layer EML (hereinafter referred to as “third light emitting layer EML3”) of the third light emitting element LE3 may emit light in different wavelength bands. The first light emitting layer EML1, the second light emitting layer EML2, and the third light emitting layer EML3 may contain indium in different compositions. For example, the quantum well layer QWL of the first light emitting layer EML1, which emits light of a longer wavelength, may contain indium in a higher composition than the quantum well layer QWL of each of the second light emitting layer EML2 and the third light emitting layer EML3.

In an embodiment, at least one light emitting element LE may further include the stress relief layer SRL and the absorption layer ABL. For example, the light emitting element LE that emits light of a long wavelength greater than or equal to a given wavelength band may include the stress relief layer SRL disposed between the first semiconductor layer SEM1 and the light emitting layer EML, and may further include at least one of the first absorption layer ABL1 disposed between the first semiconductor layer SEM1 and the light emitting layer EML or the second absorption layer ABL2 disposed between the light emitting layer EML and the second semiconductor layer SEM2.

In an embodiment, the first light emitting element LE1 may emit light (for example, red light) with a longer wavelength than that of the second light emitting element LE2 and the third light emitting element LE3, and may include the stress relief layer SRL and the absorption layer ABL. The stress relief layer SRL of the first light emitting element LE1 may include at least one of the first stress relief layer SRL1 or the second stress relief layer SRL2 according to the embodiments described above. The absorption layer ABL of the first light emitting element LE1 may include at least one of the first absorption layer ABL1 or the second absorption layer ABL2 according to the embodiments described above. Accordingly, the first light emitting element LE1 may emit light of the first color with high purity. According to embodiments, the color purity of the first light emitting element LE1 and the first pixel PX1 including it may be improved without disposing a separate color filter around (for example, above) the first light emitting element LE1.

Each of the second light emitting element LE2 and the third light emitting element LE3 may include the stress relief layer SRL disposed between the light emitting layer EML (for example, the second light emitting layer EML2 or the third light emitting layer EML3) and the first semiconductor layer SEM1, or may not include the stress relief layer SRL. For example, as in the embodiment of FIG. 20, the second light emitting element LE2 and the third light emitting element LE3 may not include the stress relief layer SRL. In an embodiment, each of the first light emitting element LE1 and the second light emitting element LE2 may include the stress relief layer SRL, and the third light emitting element LE3 may not include the stress relief layer SRL. In an embodiment, each of the first light emitting element LE1, the second light emitting element LE2, and the third light emitting element LE3 may include the stress relief layer SRL. In case that at least one of the second light emitting element LE2 or the third light emitting element LE3 may include the stress relief layer SRL, the at least one light emitting element LE may optionally further include the absorption layer ABL. In case that at least one of the second light emitting element LE2 or the third light emitting element LE3 does not include the stress relief layer SRL and/or the absorption layer ABL, the first light emitting element LE1, the second light emitting element LE2, and/or the third light emitting element LE3 may have different structures.

The second insulating layer IL2 may be disposed around the light emitting elements LE to surround at least a part of the light emitting elements LE. For example, the second insulating layer IL2 may surround the side surfaces of the light emitting elements LE.

The second insulating layer IL2 may include openings exposing a part of the light emitting elements LE. For example, the second insulating layer IL2 may be opened to expose the upper surfaces (for example, one surfaces of the first semiconductor layers SEM1) of the light emitting elements LE.

The second insulating layer IL2 may include at least one insulating material and may have a single-layer or multilayer structure. In an embodiment, the second insulating layer IL2 may include at least one inorganic insulating layer including an inorganic insulating material. The second insulating layer IL2 may be omitted.

The third insulating layer IL3 may be disposed around the light emitting elements LE and/or the second insulating layer IL2. For example, the third insulating layer IL3 may be filled between the light emitting elements LE surrounded by the second insulating layer IL2. In an embodiment, the third insulating layer IL3 may be formed to have substantially the same height or a similar height to the light emitting elements LE, and thus may reduce the stepped portion caused by the light emitting elements LE.

In an embodiment, the third insulating layer IL3 may include an inorganic insulating material. In an embodiment, the third insulating layer IL3 may be formed to a height greater than or equal to the height of the light emitting elements LE and etched or planarized to have a height that is substantially equal to or similar to the height of the light emitting element LE, but is not limited thereto. In an embodiment, the third insulating layer IL3 may include an organic insulating material (for example, acryl resin, epoxy resin, phenolic resin, polyamide resin, polyimide resin, or other organic insulating materials), and the top surface of the third insulating layer IL3 may be substantially flat. The material or structure of the third insulating layer IL3 may vary depending on the embodiments.

The second electrode ET2 may be disposed on the light emitting elements LE and may be electrically connected to the light emitting elements LE. In one example, the second electrode ET2 may be disposed on the first semiconductor layers SEM1 of the light emitting elements LE and electrically connected to the first semiconductor layers SEM1.

In an embodiment, the second electrode ET2 may be entirely disposed in the display area DA. As an example, the second electrode ET2 may be disposed on the light emitting elements LE and the third insulating layer IL3, and may be formed as a common electrode shared by the pixels PX. The second electrode ET2 may be electrically connected to the second power line of the lower substrate BPL in the display area DA and/or around the display area DA to receive the second driving voltage. The shape or position of the second electrode ET2, the connection structure between the second electrode ET2 and the light emitting elements LE, the connection structure between the second electrode ET2 and the second power line, and the like may be variously changed according to embodiments.

In an embodiment, the second electrode ET2 may contain a transparent conductive material (for example, ITO, IZO, ITZO, ZnO, or other transparent conductive materials), and may be substantially transparent. Accordingly, light generated from the light emitting elements LE may pass through the second electrode ET2 and be emitted to the upper side of the display device 10.

The fourth insulating layer IL4 may be disposed on the second electrode ET2. For example, the fourth insulating layer IL4 may be entirely disposed in the display area DA to cover the second electrode ET2. In an embodiment, the fourth insulating layer IL4 may include at least one inorganic insulating layer including an inorganic insulating material.

In an embodiment, the light emitting element layer LEL may further include additional components. For example, the light emitting element layer LEL may further include at least one of a reflective layer or a light blocking layer disposed around the light emitting elements LE (for example, between the light emitting elements LE).

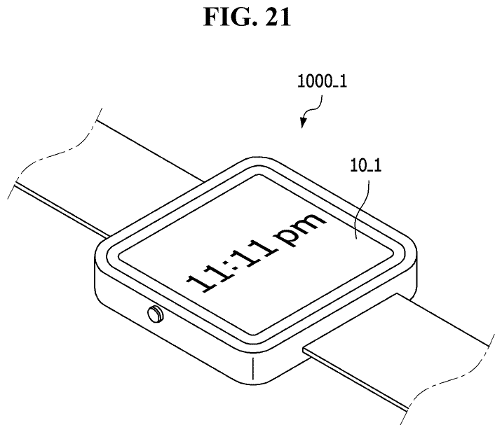

FIG. 21 is a diagram illustrating a smart watch including a display device according to an embodiment.

Referring to FIG. 21, a display device 10_1 according to an embodiment may be applied to a smart watch 1000_1 that is one of the smart devices.

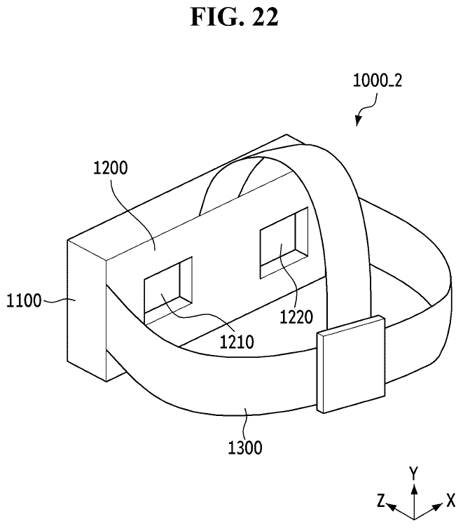

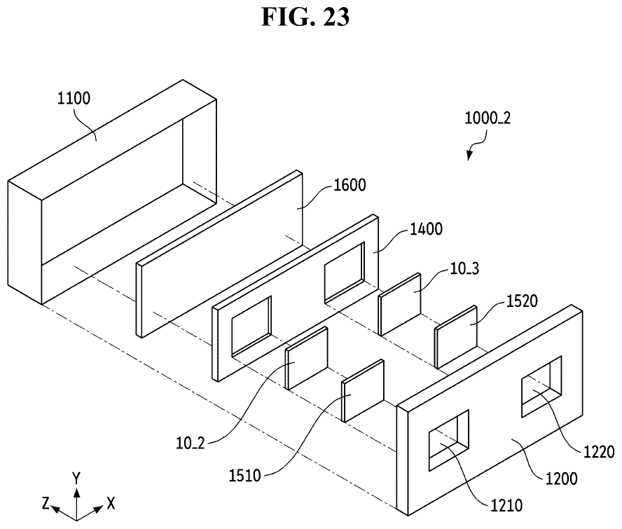

FIGS. 22 and 23 are views illustrating a head mounted display including a display device according to an embodiment.

Referring to FIGS. 22 and 23, a head-mounted display 1000_2 according to an embodiment may be a virtual reality device. The head mounted display device 1000_2 may include a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to the user's left eye, and the second display device 10_3 provides an image to the user's right eye.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and between the second display device 10_3 and the control circuit board 1600. The middle frame 1400 serves to support and fix the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through the connector. The control circuit board 1600 may convert an image source inputted from the outside into video data, and transmit the video data to the first display device 10_2 and the second display device 10_3 through the connector.

The control circuit board 1600 may transmit the video data corresponding to a left-eye image optimized for the user's left eye to the first display device 10_2, and may transmit the video data corresponding to a right-eye image optimized for the user's right eye to the second display device 10_3. By way of example, the control circuit board 1600 may transmit the same video data to the first display device 10_2 and the second display device 10_3.

The display device housing 1100 serves to accommodate the first display device 10_2, the second display device 10_3, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 22 and 23 illustrate that the first eyepiece 1210 and the second eyepiece 1220 are disposed separately, but the disclosure is not limited thereto. The first eyepiece 1210 and the second eyepiece 1220 may be combined into one. FIG. 23 illustrates non-limiting directions X, Y, and Z.

The first eyepiece 1210 may be aligned with the first display device 10_2 and the first optical member 1510, and the second eyepiece 1220 may be aligned with the second display device 10_3 and the second optical member 1520. Therefore, the user may view, through the first eyepiece 1210, the image of the first display device 10_2 magnified as a virtual image by the first optical member 1510, and may view, through the second eyepiece 1220, the image of the second display device 10_3 magnified as a virtual image by the second optical member 1520.

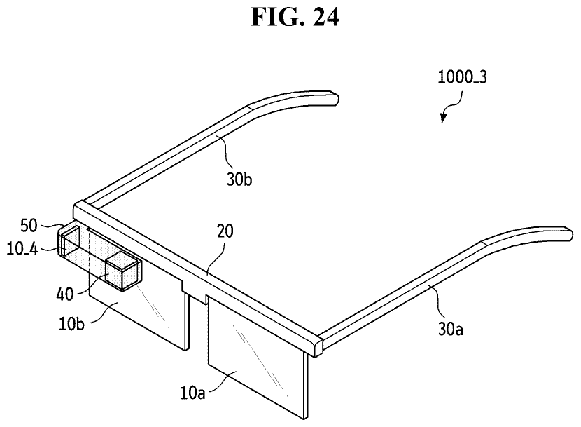

The head mounted band 1300 serves to secure the display device housing 1100 to the user's head such that the first eyepiece 1210 and the second eyepiece 1220 of the housing cover 1200 remain located on the user's left and right eyes, respectively. In case that the display device housing 1100 is implemented to be lightweight and compact, the head mounted display 1000_2 may be provided with, as shown in FIG. 24, an eyeglass frame instead of the head mounted band 1300.

In addition, the head mounted display 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 24 is a view illustrating a head mounted display including a display device according to an embodiment.

Referring to FIG. 24, a head mounted display 1000_3 according to an embodiment may be a glasses-type device. The head mounted display 1000_3 according to an embodiment may include the display device 10_4, a left eye lens 10a, a right eye lens 10b, a support frame 20, temples (or eyeglass frame legs) 30a and 30b, a reflection member 40, and a display device housing 50.

FIG. 24 illustrates that the head-mounted display 1000_3 is an eyeglasses-type display device including temples (or eyeglass frame legs) 30a and 30b, but the embodiments are not limited thereto. For example, the head-mounted display 1000_3 may be applied in various forms to other electronic devices.

The display device housing 50 may include the display device 10_4 and the reflection member 40 (or an optical path changing member). An image displayed on the display device 10_4 may be reflected by the reflection member 40 and provided to the user's right eye through the right eye lens 10b. The user may view an augmented reality image, through the right eye, in which a virtual image displayed on the display device 10_4 and a real image seen through the right eye lens 10b are combined. In an embodiment, the display device housing 50 may further include an optical member disposed between the display device 10_4 and the reflection member 40. The image displayed on the display device 10_4 may be magnified by the optical member, and may be provided to the user's right eye through the right eye lens 10b after the optical path thereof is changed by the reflection member 40.

Although FIG. 24 illustrates that the display device housing 50 is disposed at the right end of the support frame 20, the embodiment of the specification is not limited thereto. For example, the display device housing 50 may be disposed at the left end of the support frame 20, and the image displayed on the display device 10_4 may be reflected by the reflection member 40 and provided to a user's left eye through the left eye lens 10a. The user may view the image displayed on the display device 10_4 with the left eye. By way of example, the display device housing 50 may be disposed at both the left end and the right end of the support frame 20, in which case the user can view the image displayed on the display device 10_4 through both the left eye and the right eye.

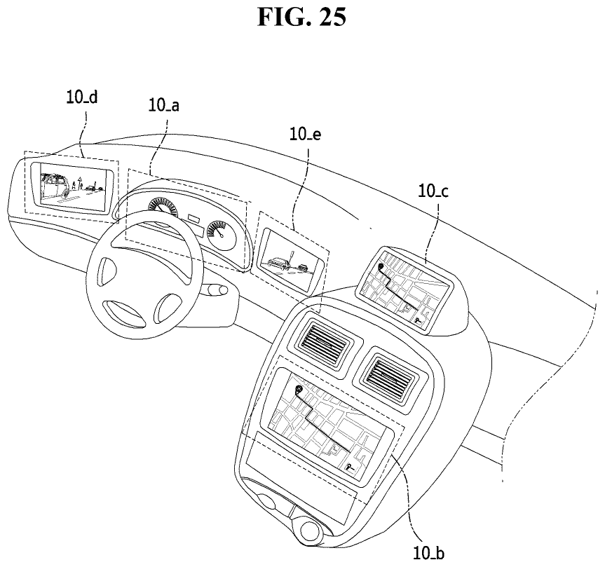

FIG. 25 is a diagram illustrating a dashboard of an automobile and a center fascia including display devices according to an embodiment. FIG. 25 illustrates a vehicle to which the display devices 10_a, 10_b, 10_c, 10_d, and 10_e according to an embodiment are applied.

Referring to FIG. 25, the display devices 10_a, 10_b, and 10_c according to an embodiment may be applied to the dashboard of the automobile, the center fascia of the automobile, or the center information display (CID) of the dashboard of the automobile. Further, the display devices 10_d, and 10_e according to an embodiment may be applied to a room mirror display instead of side mirrors of the automobile.

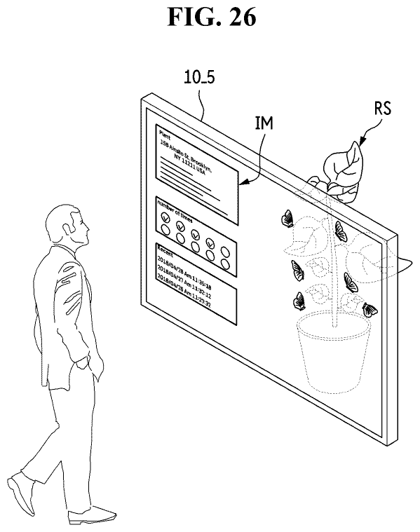

FIG. 26 is a diagram illustrating a transparent display device including a display device according to an embodiment.

Referring to FIG. 26, a display device 10_5 according to an embodiment may be applied to the transparent display device. The transparent display device may display an image IM, and also may transmit light. Thus, a user located on the front side of the transparent display device can view an object RS or a background on the rear side of the transparent display device as well as the image IM displayed on the display device 10_5. In case that the display device 10_5 is applied to the transparent display device, the substrate of the display device 10_5 may include a light transmitting portion capable of transmitting light or may be made of a material capable of transmitting light.

FIGS. 21 to 26 shows various examples of electronic devices that may include the light emitting elements LE and/or the display device 10 according to the previously described embodiments. However, the electronic devices that may include the light emitting elements LE and/or the display device 10 according to the embodiments are not limited to the electronic devices shown in FIGS. 21 to 26. For example, the display device 10 including the light emitting elements LE according to the embodiments may also be included in other types or structures of electronic devices and may be used as the display screen of the electronic device.

The electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A light emitting element comprising:
a first semiconductor layer;
a stress relief layer disposed on the first semiconductor layer;
a light emitting layer disposed on the stress relief layer; and
a second semiconductor layer disposed on the light emitting layer,
the light emitting element further comprising an absorption layer disposed above or below the light emitting layer and absorbing light of a wavelength band corresponding to a bandgap energy of the stress relief layer.

2. The light emitting element of claim 1, wherein the stress relief layer, the light emitting layer and the absorption layer contain a nitride-based semiconductor material containing indium.

3. The light emitting element of claim 2, wherein the stress relief layer comprises an indium-containing layer containing a nitride-based semiconductor material containing indium, and
the light emitting layer comprises a quantum well layer containing a nitride-based semiconductor material containing indium at a composition higher than an indium composition of the indium-containing layer.

4. The light emitting element of claim 3, wherein an indium composition of the absorption layer is higher than the indium composition of the indium-containing layer and lower than an indium composition of the quantum well layer.

5. The light emitting element of claim 3, wherein an indium composition of the quantum well layer is about 25% or more.

6. The light emitting element of claim 3, wherein a bandgap energy of the absorption layer has a value between a bandgap energy of the indium-containing layer and a bandgap energy of the quantum well layer.

7. The light emitting element of claim 3, wherein the stress relief layer is formed as multiple layers comprising a plurality of indium-containing layers and a plurality of intermediate layers alternately stacked with the plurality of indium-containing layers, and
the absorption layer is formed as a single layer containing indium.

8. The light emitting element of claim 7, wherein a thickness of the absorption layer is in a range of about 10 nm to about 100 nm.

9. The light emitting element of claim 2, wherein the stress relief layer comprises at least one of:
a first stress relief layer disposed on the first semiconductor layer and containing indium at a composition of less than about 10%; and
a second stress relief layer disposed on the first semiconductor layer or the first stress relief layer and containing indium at a composition of about 10% or more.

10. The light emitting element of claim 1, wherein the absorption layer comprises at least one of:
a first absorption layer disposed between the first semiconductor layer and the light emitting layer; and
a second absorption layer disposed between the light emitting layer and the second semiconductor layer.

11. The light emitting element of claim 10, wherein the first absorption layer is disposed on at least one of between the stress relief layer and the light emitting layer, between the first semiconductor layer and the stress relief layer, or between a first stress relief layer and a second stress relief layer in the stress relief layer.

12. The light emitting element of claim 10, wherein the light emitting layer comprises quantum well layers and barrier layers alternately stacked with each other, and
the second absorption layer is disposed between a last quantum well layer and a last barrier layer of the light emitting layer, or on top of the last barrier layer.

13. The light emitting element of claim 1, wherein the absorption layer contains a first conductivity type dopant or a second conductivity type dopant, and a doping concentration of the first conductivity type dopant or the second conductivity type dopant is about 10¹⁸/cm³ or more.

14. The light emitting element of claim 1, wherein a wavelength of light emitted from the light emitting layer is about 600 nm or more.

15. A display device comprising:
a first electrode, a second electrode, and a light emitting element electrically connected between the first electrode and the second electrode,
wherein the light emitting element comprises:
a first semiconductor layer and a second semiconductor layer overlapping each other;
a light emitting layer disposed between the first semiconductor layer and the second semiconductor layer;
a stress relief layer disposed between the first semiconductor layer and the light emitting layer; and
an absorption layer disposed on at least one of between the first semiconductor layer and the light emitting layer or between the second semiconductor layer and the light emitting layer, and absorbing light of a wavelength band corresponding to a band gap energy of the stress relief layer.

16. The display device of claim 15, wherein the light emitting layer, the stress relief layer, and the absorption layer contain a nitride-based semiconductor material containing indium,
an indium composition of the absorption layer is higher than an indium composition of an indium-containing layer comprised in the stress relief layer, and lower than an indium composition of a quantum well layer comprised in the light emitting layer, and a bandgap energy of the absorption layer has a value between a bandgap energy of the indium-containing layer and a bandgap energy of the quantum well layer.

17. The display device of claim 15, wherein the stress relief layer is formed as multiple layers comprising a plurality of indium-containing layers and a plurality of intermediate layers alternately stacked with the plurality of indium-containing layers, and
the absorption layer is formed as a single layer containing indium and having a thickness in a range of about 10 nm to about 100 nm.

18. The display device of claim 15, wherein the absorption layer contains a first conductivity type dopant or a second conductivity type dopant.

19. An electronic device including a display device, the display device comprising:
a first electrode, a second electrode, and a light emitting element electrically connected between the first electrode and the second electrode,
wherein the light emitting element comprises:
a first semiconductor layer and a second semiconductor layer overlapping each other;
a light emitting layer disposed between the first semiconductor layer and the second semiconductor layer;
a stress relief layer disposed between the first semiconductor layer and the light emitting layer; and
an absorption layer disposed at least one of between the first semiconductor layer and the light emitting layer or between the second semiconductor layer and the light emitting layer, and absorbing light of a wavelength band corresponding to a band gap energy of the stress relief layer.

20. The electronic device of claim 19, wherein the light emitting layer, the stress relief layer, and the absorption layer contain a nitride-based semiconductor material containing indium, and
an indium composition of the absorption layer is higher than an indium composition of an indium-containing layer comprised in the stress relief layer, and lower than an indium composition of a quantum well layer comprised in the light emitting layer.
